(19) United States
(12) Patent Application Publication
(10) Pub. No.: US 2025/0294968 A1
(43) Pub. Date: Sep. 18, 2025

(54) DISPLAY DEVICE, WEARABLE ELECTRONIC DEVICE, AND METHOD OF MANUFACTURING DISPLAY DEVICE

(71) Applicant: Samsung Display Co., LTD., Yongin-si (KR)

(72) Inventor: Chun Gi YOU, Yongin-si (KR)

(21) Appl. No.: 18/988,624

(22) Filed: Dec. 19, 2024

(30) Foreign Application Priority Data
Mar. 15, 2024 (KR) 10-2024-0036367

(51) Int. Cl. H10K 59/122; H10K 59/12; H10K 59/80

(52) U.S. Cl. CPC H10K 59/122; H10K 59/1201; H10K 59/80518

(57) ABSTRACT

A display device may include first, second, and third sub-pixels including a reflective electrode above a base layer, a planarization layer above the reflective electrode, having a flat upper surface, defining a via exposing a portion of the reflective electrode, and including first and second side surfaces facing each other with the via therebetween, an anode electrode above the planarization layer, above an area of the reflective electrode exposed by the via, and directly connected to the reflective electrode, a light-emitting structure above the anode electrode, and a cathode electrode above the light-emitting structure, wherein the first sub-pixel further includes a buffer pattern between the base layer and the reflective electrode, and wherein a separation distance between the anode electrode and the reflective electrode in the first sub-pixel is less than a separation distance between the anode electrode and the reflective electrode in the second and third sub-pixels.

### CROSS-REFERENCE TO RELATED APPLICATION

The present application claims priority to, and the benefit of, Korean Patent Application No. 10-2024-0036367, filed on Mar. 15, 2024, in the Korean Intellectual Property Office, the entire disclosure of which is incorporated herein by reference.

### BACKGROUND

### 1. Field

The disclosure relates to a display device, a wearable electronic device, and a method of manufacturing the display device.

### 2. Description of the Related Art

As interest in an information display is recently increased, research and development on a display device is continuously being conducted.

### SUMMARY

The disclosure may provide a display device with improved reliability, a wearable electronic device, and a method of manufacturing the display device.

One or more embodiments of the present disclosure may provide a display device including a first sub-pixel, a second sub-pixel, and a third sub-pixel, the first sub-pixel, the second sub-pixel, and the third sub-pixel including a reflective electrode above a base layer, a planarization layer above the reflective electrode, having a flat upper surface, defining a via exposing a portion of the reflective electrode, and including a first side surface and a second side surface facing each other with the via therebetween, an anode electrode above the planarization layer, above an area of the reflective electrode exposed by the via, and directly connected to the reflective electrode, a light-emitting structure above the anode electrode, and a cathode electrode above the light-emitting structure, wherein the first sub-pixel further includes a buffer pattern between the base layer and the reflective electrode, and wherein a separation distance between the anode electrode and the reflective electrode in the first sub-pixel is less than a separation distance between the anode electrode and the reflective electrode in the second sub-pixel and the third sub-pixel.

The reflective electrode may be directly on the base layer in the second sub-pixel and the third sub-pixel.

The buffer pattern may include an insulating material.

In the first sub-pixel, the anode electrode may be on the first side surface and the second side surface of the planarization layer, and may be on the flat upper surface connected to the first side surface and the second side surface.

In the first sub-pixel, a sidewall of the via may be closer to the buffer pattern than one end of the reflective electrode.

One end of the reflective electrode may be exposed through the via.

The display device may further include a pixel-defining layer above the anode electrode and the planarization layer, and a protrusion pattern above the pixel-defining layer.

The pixel-defining layer may include a first inorganic insulating layer, a second inorganic insulating layer, and a third inorganic insulating layer sequentially stacked.

The first inorganic insulating layer may be above the anode electrode in the via.

The protrusion pattern may include a first protrusion pattern above the pixel-defining layer, and having a first width, a second protrusion pattern above the first protrusion pattern, and having a second width that is less than the first width, and a third protrusion pattern above the second protrusion pattern, and having a third width that is greater than the second width.

The display device may further include one or more trenches formed by recessing at least a portion of the pixel-defining layer in a boundary area between the first sub-pixel and the second sub-pixel and in a boundary area between the second sub-pixel and the third sub-pixel.

The light-emitting structure may include a first light-emitting layer commonly in the first sub-pixel, the second sub-pixel, and the third sub-pixel, and configured to emit light of a first color, and a second light-emitting layer above the first light-emitting layer, and configured to emit light of a second color.

The first light-emitting layer of the first sub-pixel and the second light-emitting layer of the second sub-pixel may be separated.

The light-emitting structure may further include a third light-emitting layer above the second light-emitting layer, and configured to emit light of a third color.

One or more embodiments of the present disclosure may provide a wearable electronic device including a display panel including a first sub-pixel, a second sub-pixel, and a third sub-pixel, the first sub-pixel, the second sub-pixel, and the third sub-pixel including a reflective electrode above a base layer, a planarization layer above the reflective electrode, having a flat upper surface, defining a via exposing a portion of the reflective electrode, and including a first side surface and a second side surface facing each other with the via therebetween, an anode electrode above the planarization layer, above an area of the reflective electrode exposed by the via, directly connected to the reflective electrode, and on the first side surface, the second side surface, and the flat upper surface connected to the first side surface and the second side surface, respectively, a light-emitting structure above the anode electrode, and a cathode electrode above the light-emitting structure, and a lens on the display panel, wherein the first sub-pixel further includes a buffer pattern between the base layer and the reflective electrode.

The reflective electrode may be directly above the base layer in the second sub-pixel and the third sub-pixel.

A separation distance between the anode electrode and the reflective electrode in the first sub-pixel may be less than a separation distance between the anode electrode and the reflective electrode in the second sub-pixel and in the third sub-pixel.

One or more embodiments of the present disclosure may provide a method of manufacturing a display device, the method including forming a buffer pattern above a base layer of a first sub-pixel, forming a first reflective electrode above the buffer pattern, forming a second reflective electrode directly on the base layer of a second sub-pixel, forming a third reflective electrode directly on the base layer of a third sub-pixel, forming a planarization layer covering the first reflective electrode, the second reflective electrode, and the third reflective electrode, and having a flat upper surface, by applying an insulating material layer on the first reflective electrode, the second reflective electrode, and the third reflective electrode, by arranging a mask on the insulating material layer, and by performing a photolithography process, and forming a light-emitting element above the planarization layer.

A thickness of the insulating material layer on the first reflective electrode, a thickness of the insulating material layer on the second reflective electrode, and a thickness of the insulating material layer on the third reflective electrode may be substantially equal, wherein the insulating material layer on the first reflective electrode protrudes upwardly further than the insulating material layer on the second reflective electrode and the insulating material layer on the third reflective electrode, and wherein one area of the insulating material layer on the first reflective electrode is etched through a dry etching process of the photolithography process.

The method may further include forming a pixel-defining layer above the light-emitting element, wherein the planarization layer defines a via exposing an area of the first reflective electrode, an area of the second reflective electrode, and an area of the third reflective electrode, and includes a first side surface and a second side surface facing each other with the via therebetween, and wherein the pixel-defining layer is in the via.

A display device and a wearable electronic device according to embodiments may form a planarization layer located on a reflective electrode of sub-pixels through an etching process. Therefore, a chemical mechanical polishing (CMP) process may be omitted. Accordingly, a process dispersion defect that may occur during the CMP process may be reduced, thereby improving reliability.

According to embodiments, an anode electrode may be positioned inside a via of the planarization layer formed through the above-described etching process. Therefore, the reflective electrode exposed by the via and the anode electrode may directly contact each other, and thus the contact area between the reflective electrode and the anode electrode may be increased. Accordingly, reliability of the display device and the wearable electronic device may be improved.

An aspect according to embodiments is not limited to the contents above, and further various effects are included in the present specification.

### BRIEF DESCRIPTION OF THE DRAWINGS

FIG. 1 is a schematic block diagram illustrating a display device in accordance with one or more embodiments.

FIG. 2 is a schematic block diagram illustrating one or more embodiments of one of sub-pixels of FIG. 1.

FIG. 3 is a schematic circuit diagram illustrating one or more embodiments of the sub-pixel of FIG. 2.

FIG. 4 is a schematic plan view illustrating one or more embodiments of the display device of FIG. 1.

FIG. 5 is a schematic exploded perspective view illustrating a portion of a display panel of FIG. 4.

FIG. 6A is a schematic plan view illustrating one or more embodiments of one of pixels of FIG. 5.

FIG. 6B is a schematic plan view illustrating one or more other embodiments of one of the pixels of FIG. 5.

FIG. 6C is a schematic plan view illustrating still one or more other embodiments of one of the pixels of FIG. 5.

FIG. 7 is a schematic cross-sectional view illustrating one or more embodiments of a pixel taken along the line I˜I′ of FIG. 6A.

FIG. 8 is a schematic cross-sectional view illustrating one or more other embodiments of the pixel taken along the line I˜I′ of FIG. 6A.

FIG. 9 is a schematic cross-sectional view illustrating one or more embodiments of a light-emitting structure included in one of first to third light-emitting elements of FIG. 7.

FIG. 10 is a schematic cross-sectional view illustrating one or more other embodiments of the light-emitting structure included in one of the first to third light-emitting elements of FIG. 7.

FIGS. 11A and 11B are schematic enlarged cross-sectional views of a portion of the display device of FIG. 7.

FIGS. 12 to 16 are schematic cross-sectional views illustrating a method of manufacturing a display device according to one or more embodiments.

FIG. 17 is a schematic cross-sectional view illustrating still one or more other embodiments of the pixel taken along the line I˜I′ of FIG. 6A.

FIG. 18 is an enlarged schematic cross-sectional view of a portion of the display device of FIG. 17.

FIG. 19 is a schematic block diagram illustrating one or more embodiments of a display system.

FIG. 20 is a schematic perspective view illustrating an application example of the display system of FIG. 19.

FIG. 21 is a schematic diagram illustrating a form in which a user wears a head-mounted display device of FIG. 20.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

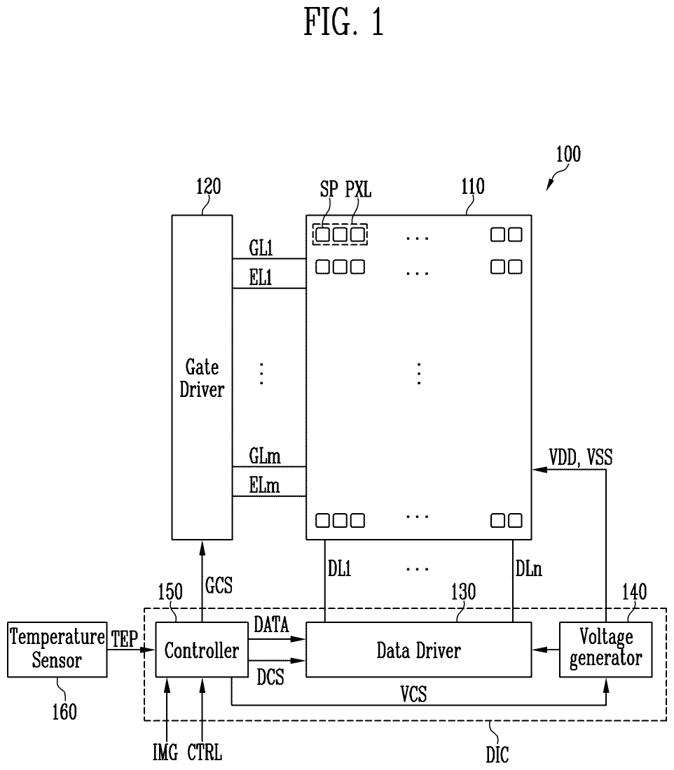

FIG. 1 is a schematic block diagram illustrating a display device 100 in accordance with one or more embodiments.

Referring to FIG. 1, the display device 100 may include a display panel 110 (or a display component), a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, each of the sub-pixels SP may generate light of a corresponding color, such as red, green, blue, cyan, magenta, or yellow. Two or more sub-pixels among the sub-pixels SP may configure one pixel PXL. For example, as shown in FIG. 1, three sub-pixels may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm connected to the sub-pixels SP of the row direction may be further provided. In this case, the gate driver 120 may include an emission control driver configured to control the first to m-th emission control lines EL1 to Elm. The emission control driver may operate under control of the controller 150.

The gate driver 120 may be located on one side of the display panel 110. However, embodiments are not limited thereto. For example, the gate driver 120 may be divided into two or more physically and/or logically divided drivers, and such drivers may be respectively located on one side of the display panel 110, and on another side of the display panel 110 opposite the one side. As described above, the gate driver 120 may be located around the display panel 110 in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. In case that the gate signal is applied to each of the first to m-th gate lines GL1 to GLm, the data signals corresponding to the image data DATA may be applied to the data lines DL1 to DLn. Accordingly, the corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages, and may provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level that is lower than that of the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light-emitting elements of the sub-pixels SP, a reference voltage (e.g., predetermined reference voltage) may be applied to the first to n-th data lines DL1 to DLn, and the voltage generator 140 may generate such a reference voltage.

The controller 150 may control overall operations of the display device 100. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110, and may output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, or the controller 150 may be provided as a component distinguished from the driver integrated circuit DIC.

The display device 100 may include at least one temperature sensor 160. The temperature sensor 160 may be configured to sense a temperature around the temperature sensor 160, and may generate temperature data TEP indicating the sensed temperature. In embodiments, the temperature sensor 160 may be located adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components, such as the data driver 130 and/or the voltage generator 140.

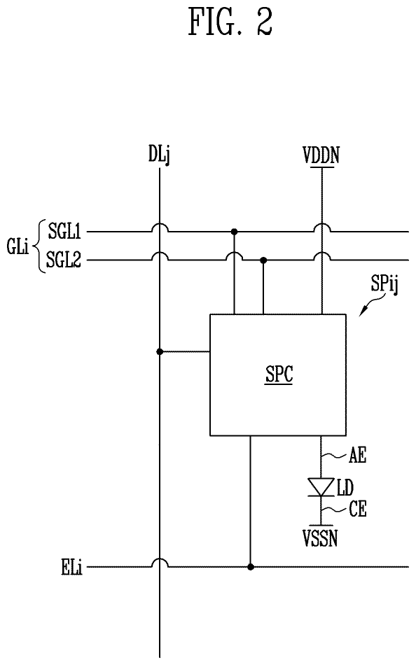

FIG. 2 is a schematic block diagram illustrating one or more embodiments of one of the sub-pixels of FIG. 1. In FIG. 2, among the sub-pixels SP of FIG. 1, a sub-pixel SPij arranged in an i-th row (i is an integer greater than or equal to 1 and less than or equal to m) and in a j-th column (j is an integer greater than or equal to 1 and less than or equal to n) is shown as an example.

Referring to FIG. 2, the sub-pixel SPij may include a sub-pixel circuit SPC and a light-emitting element LD.

The light-emitting element LD may be connected between a first power voltage node VDDN and a second power voltage node VSSN. At this time, the first power voltage node VDDN is a node that transmits the first power voltage VDD of FIG. 1, and the second power voltage node VSSN may be a node that transmits the second power voltage VSS of FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light-emitting element LD according to signals received through such signal lines.

The sub-pixel circuit SPC may operate in response to a gate signal received through the i-th gate line GLi. The i-th gate line GLi may include one or more sub gate lines. In embodiments, as shown in FIG. 2, when the i-th gate line GLi includes two or more sub gate lines, the sub-pixel circuit SPC may operate in response to gate signals received through the corresponding sub gate lines.

The sub-pixel circuit SPC may operate in response to an emission control signal received through the i-th emission control line ELi. In embodiments, the i-th emission control line ELi may include one or more sub emission control lines. In case that the i-th emission control line ELi includes two or more sub emission control lines, the sub-pixel circuit SPC may operate in response to emission control signals received through the corresponding sub emission control lines.

The sub-pixel circuit SPC may receive a data signal through the j-th data line DLj. The sub-pixel circuit SPC may store a voltage corresponding to the data signal in response to at least one of the gate signals received through the first and second sub gate lines SGL1 and SGL2. The sub-pixel circuit SPC may adjust a current flowing from the first power voltage node VDDN to the second power voltage node VSSN through the light-emitting element LD according to the stored voltage, and in response the emission control signal received through the i-th emission control line ELi. Accordingly, the light-emitting element LD may generate light of a luminance corresponding to the data signal.

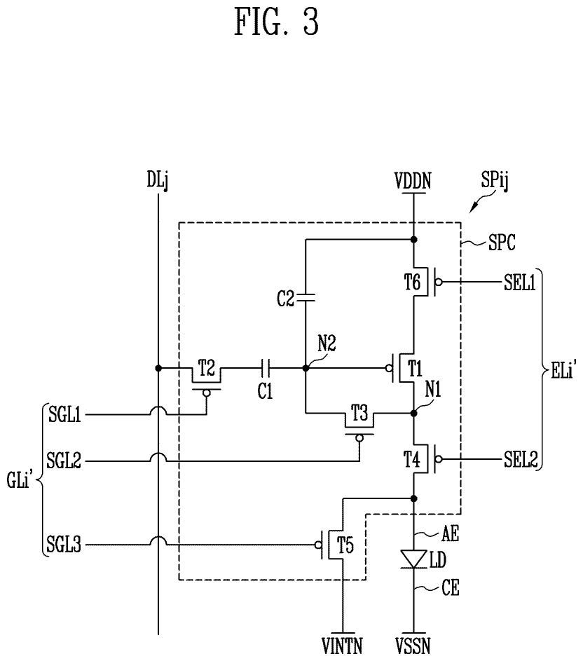

FIG. 3 is a schematic circuit diagram illustrating one or more embodiments of the sub-pixel of FIG. 2.

Referring to FIG. 3, the sub-pixel SPij may include a sub-pixel circuit SPC and a light-emitting element LD.

The sub-pixel circuit SPC may be connected to an i-th gate line GLi′, an i-th emission control line ELi′, and the j-th data line DLj. Compared to the i-th gate line GLi of FIG. 2, the i-th gate line GLi′ may further include a third sub gate line SGL3. Compared to the i-th emission control line ELi of FIG. 2, the i-th emission control line ELi′ may include a first sub emission control line SEL1 and a second sub emission control line SEL2.

The sub-pixel circuit SPC may include first to sixth transistors T1 to T6, and first and second capacitors C1 and C2.

The first transistor T1 may be connected between the first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 may be connected to the first sub gate line SGL1, and thus the second transistor T2 may be turned on in response to a gate signal of the first sub gate line SGL1. The second transistor T2 may be referred to as a switching transistor.

The third transistor T3 may be connected between the first node N1 and the second node N2. A gate of the third transistor T3 may be connected to the second sub gate line SGL2, and thus the third transistor T3 may be turned on in response to a gate signal of the second sub gate line SGL2.

The fourth transistor T4 may be connected between the first node N1 and the anode electrode AE of the light-emitting element LD. A gate of the fourth transistor T4 may be connected to the second sub emission control line SEL2, and thus the fourth transistor T4 may be turned on in response to an emission control signal of the second sub emission control line SEL2.

The fifth transistor T5 may be connected between the anode electrode AE of the light-emitting element LD and an initialization voltage node VINTN. The initialization voltage node VINTN may be configured to transmit an initialization voltage. In embodiments, the initialization voltage may be provided by the voltage generator 140 of FIG. 1. In other embodiments, the initialization voltage may be provided by an external device of the display device 100. A gate of the fifth transistor T5 may be connected to the third sub gate line SGL3, and thus the fifth transistor T5 may be turned on in response to a gate signal of the third sub gate line SGL3.

The sixth transistor T6 may be connected between the first power voltage node VDDN and the first transistor T1. A gate of the sixth transistor T6 may be connected to the first sub emission control line SEL1, and thus the sixth transistor T6 may be turned on in response to an emission control signal of the first sub emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as one of various types of circuits including a plurality of transistors and one or more capacitors. For example, the sub-pixel circuit SPC may include two transistors and one capacitor. According to embodiments of the sub-pixel circuit SPC, the number of sub gate lines included in the i-th gate line GLi′, and the number of sub emission control lines included in the i-th emission control line ELi′ may vary.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

In embodiments, the first to sixth transistors T1 to T6 may include an amorphous silicon semiconductor, a monocrystalline silicon semiconductor, a polycrystalline silicon semiconductor, an oxide semiconductor, and the like.

The light-emitting element LD may include the anode electrode AE, the cathode electrode CE, and a light-emitting layer. The light-emitting layer may be located between the anode electrode AE and the cathode electrode CE. After the data signal transmitted through the j-th data line DLj is reflected in the voltage of the second node N2, when the emission control signals of the first and second sub emission control lines SEL1 and SEL2 are enabled to a low level, the fourth and sixth transistors T4 and T6 may be turned on. In addition, the first transistor T1 may be turned on according to the voltage of the second node N2, and thus a current may flow from the first power voltage node VDDN to the second power voltage node VSSN. The light-emitting element LD may emit light according to an amount of the flowing current.

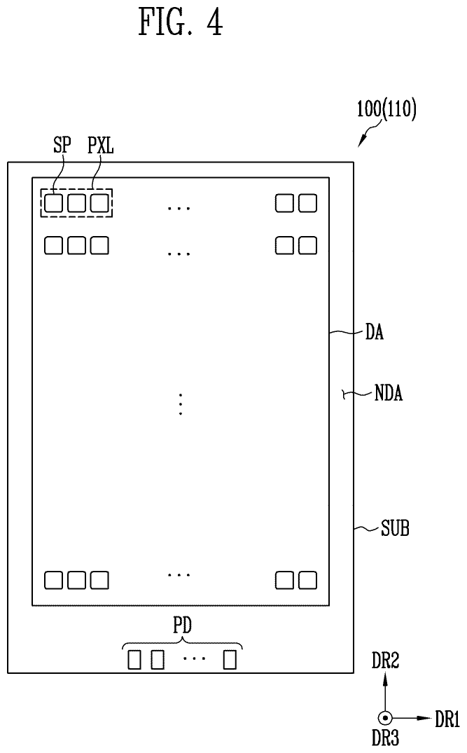

FIG. 4 is a schematic plan view illustrating one or more embodiments of the display device 100 of FIG. 1. For convenience, FIG. 4 schematically shows a structure of the display device 100, for example, the display panel 110 provided in the display device 100, based on a display area DA where an image is displayed.

Referring to FIG. 4, the display panel 110 may include the display area DA and a non-display area NDA. The display panel 110 may display an image through the display area DA. The non-display area NDA may be located around the display area DA.

The display panel 110 may include a substrate SUB, the sub-pixels SP, and pads PD.

In case that the display panel 110 is used as a display screen of a head-mounted display (HMD), a virtual reality (VR) device, a mixed reality (MR) device, an augmented reality (AR) device, or the like, the display panel 110 may be positioned very close to user's eyes. In this case, sub-pixels SP of a relatively high integration degree may be required. To increase an integration degree of the sub-pixels SP, the substrate SUB may be provided as a silicon substrate (or a silicon wafer), but is not limited thereto. The sub-pixels SP and/or the display panel 110 may be formed on the substrate SUB, which is the silicon substrate. The display device 100 including the display panel 110 formed on the substrate SUB, which is the silicon substrate, may be referred to as an OLED on silicon (OLEDoS) display device.

The sub-pixels SP may be located in the display area DA on the substrate SUB. The sub-pixels SP may be arranged in a matrix shape along a first direction DR1, and along a second direction DR2 crossing the first direction DR1, but an arrangement shape of the sub-pixels SP is not limited. For example, the sub-pixels SP may be arranged in a zigzag shape along the first direction DR1 and the second direction DR2. For example, the sub-pixels SP may be arranged in a PENTILE™ shape (PENTILE™ being a registered trademark of Samsung Display Co., Ltd., Republic of Korea). The first direction DR1 may be a row direction, and the second direction DR2 may be a column direction.

Two or more sub-pixels SP among the plurality of sub-pixels SP may configure one pixel PXL.

A component for controlling the sub-pixels SP may be located in the non-display area NDA on the substrate SUB. For example, lines connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, or the temperature sensor 160 of FIG. 1 may be integrated in the non-display area NDA of the display panel 110. In embodiments, the gate driver 120 of FIG. 1 may be mounted on the display panel 110, and may be located in the non-display area NDA. In other embodiments, the gate driver 120 may be implemented as an integrated circuit separated from the display panel 110. In embodiments, the temperature sensor 160 may be located in the non-display area NDA to sense a temperature of the display panel 110.

The pads PD may be located in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel 110 to other components of the display device 100. In embodiments, voltages and signals suitable for an operation of components included in the display panel 110 may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in case that the gate driver 120 is mounted on the display panel 110, the gate control signal GCS may be transmitted from the driver integrated circuit DIC to the gate driver 120 through the pads PD.

In embodiments, a circuit board may be electrically connected to the pads PD using a conductive adhesive member, such as an anisotropic conductive film. At this time, the circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes, such as a polygon, a circle, a semicircle, and an ellipse.

In embodiments, the display panel 110 may have a flat display surface. In other embodiments, the display panel 110 may have a display surface that is at least partially round. In embodiments, the display panel 110 may be bendable, foldable, or rollable. In these cases, the display panel 110 and/or the substrate SUB may include materials having a flexible property.

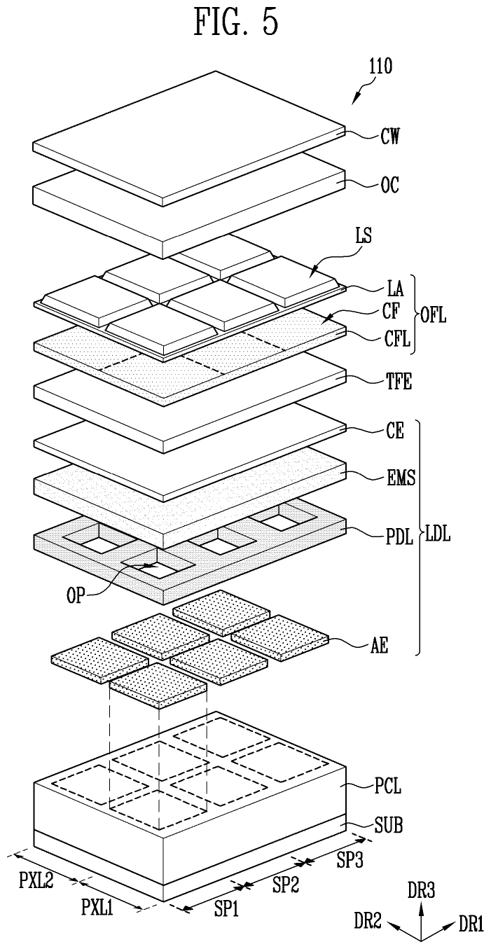

FIG. 5 is a schematic exploded perspective view illustrating a portion of the display panel 110 of FIG. 4. In FIG. 5, for clear and concise description, a portion of the display panel 110 corresponding to two pixels PXL1 and PXL2 among the pixels PXL of FIG. 4 is schematically shown. A portion of the display panel 110 corresponding to remaining pixels may be similarly configured.

Referring to FIGS. 4 and 5, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 5, the first to third sub-pixels SP1, SP2, and SP3 have quadrangle shapes when viewed from a third direction DR3 crossing the first and second directions DR1 and DR2, and have sizes equal to each other. However, embodiments are not limited thereto. According to one or more embodiments, the first to third sub-pixels SP1, SP2, and SP3 may be modified to have various shapes.

The display panel 110 may include the substrate SUB, a pixel circuit layer PCL, a light-emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL may be located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include copper, but embodiments are not limited thereto.

The circuit elements may include the sub-pixel circuit SPC of FIG. 2 of each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, in case that the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, in case that the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, a data line, and the like. The lines may further include lines connected to the first power voltage node VDDN of FIG. 2. In addition, the lines may further include a line connected to the second power voltage node VSSN of FIG. 2.

The light-emitting element layer LDL may include the anode electrode AE, a pixel-defining layer PDL, a light-emitting structure EMS, and the cathode electrode CE.

The anode electrode AE may be located on the pixel circuit layer PCL. The anode electrode AE may contact the circuit elements of the pixel circuit layer PCL. The anode electrode AE may include an opaque conductive material capable of reflecting light, but embodiments are not limited thereto.

The pixel-defining layer PDL may be located on the anode electrode AE. The pixel-defining layer PDL may include an opening OP exposing a portion of each of the anode electrodes AE. The opening OP of the pixel-defining layer PDL may be understood as emission areas corresponding to the first to third sub-pixels SP1 to SP3, respectively.

In embodiments, the pixel-defining layer PDL may include an inorganic material. In this case, the pixel-defining layer PDL may include a plurality of stacked inorganic layers. For example, the pixel-defining layer PDL may include silicon oxide SiOx and silicon nitride SiNx. In other embodiments, the pixel-defining layer PDL may include an organic material. However, a material of the pixel-defining layer PDL is not limited thereto.

The light-emitting structure EMS may be located on the anode electrode AE exposed by the opening OP of the pixel-defining layer PDL. The light-emitting structure EMS may include a light-emitting layer configured to generate light, an electron transport layer configured to transport an electron, a hole transport layer configured to transport a hole, and the like.

In embodiments, the light-emitting structure EMS may fill the opening OP of the pixel-defining layer PDL, and may be entirely located on the pixel-defining layer PDL. In other words, the light-emitting structure EMS may extend across the first to third sub-pixels SP1 to SP3. In this case, at least a portion of layers in the light-emitting structure EMS may be disconnected or bent at boundaries between the first to third sub-pixels SP1 to SP3. However, embodiments are not limited thereto. For example, portions of the light-emitting structure EMS corresponding to the first to third sub-pixels SP1 to SP3 may be separated from each other, and each of the portions may be located in the opening OP of the pixel-defining layer PDL.

The cathode electrode CE may be located on the light-emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light-emitting structure EMS. The cathode electrode CE may be formed of a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or a mixture thereof. However, a material of the cathode electrode CE is not limited thereto.

It may be understood that one of the anode electrodes AE, a portion of the light-emitting structure EMS overlapping it, and a portion of the cathode electrode CE overlapping it configure one light-emitting element (refer to “LD” of FIG. 2). In other words, each of the light-emitting elements of the first to third sub-pixels SP1 to SP3 may include one anode electrode AE, a portion of the light-emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light-emitting layer of the light-emitting structure EMS to form excitons, and in case that the excitons transits from an excited state to a ground state, light may be generated. A luminance of light may be determined according to an amount of a current flowing through the light-emitting layer. According to a configuration of the light-emitting layer, a wavelength range of the generated light may be determined.

The encapsulation layer TFE may be located on the cathode electrode CE. The encapsulation layer TFE may cover the light-emitting element layer LDL and/or the pixel circuit layer PCL. The encapsulation layer TFE may be configured to reduce or prevent permeation of oxygen, moisture, and/or the like to the light-emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. The organic layer may include an organic insulating material, such as acrylic (polyacrylates resin), epoxy resin, phenolic resin, polyamides resin, polyimides resin, unsaturated polyesters resin, polyphenylenethers resin, polyphenylenesulfides resin, or benzocyclobutene (BCB). However, materials of the organic layer and the inorganic layer of the encapsulation layer TFE are not limited thereto.

To improve an encapsulation efficiency of the encapsulation layer TFE, the encapsulation layer TFE may further include a thin film including aluminum oxide (AlOx). The thin film including the aluminum oxide may be positioned on an upper surface of the encapsulation layer TFE facing the optical functional layer OFL and/or a lower surface of the encapsulating layer TFE facing the light-emitting element layer LDL.

The thin film including the aluminum oxide may be formed through atomic layer deposition (ALD) method. However, embodiments are not limited thereto. The encapsulation layer TFE may further include a thin film formed of at least one of various materials suitable for improving the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured to filter the light emitted from the light-emitting structure EMS, and to selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light-emitting structure EMS of each sub-pixel, at least a portion of the color filters CF may be omitted.

The lens array LA may be located on the color filter layer CFL. The lens array LA may include lenses LS respectively corresponding to the first to third sub-pixels SP1 to SP3. Each of the lenses LS may improve light output efficiency by outputting the light emitted from the light-emitting structure EMS to an intended path. The lens array LA may have a relatively high refractive index. For example, the lens array LA may have a refractive index higher than that of the overcoat layer OC. In embodiments, the lenses LS may include an organic material. In embodiments, the lenses LS may include an acrylic (acrylate) material. However, a material of the lenses LS is not limited thereto.

In embodiments, compared to the opening OP of the pixel-defining layer PDL, at least a portion of the color filters CF of the color filter layer CFL and at least a portion of the lenses LS of the lens array LA may be shifted in a direction parallel to the plane defined by the first and second directions DR1 and DR2. For example, in a central area of the display area DA, a center of the color filter and a center of the lens may be aligned with, or may overlap with, a center of the opening OP of the corresponding pixel definition layer PDL when viewed in the third direction DR3. For example, in the central area of the display area DA, the opening OP of the pixel-defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a plane direction from the center of the opening OP of the corresponding pixel-defining layer PDL when viewed in the third direction DR3. For example, in the area adjacent to the non-display area NDA in the display area DA, the opening OP of the pixel-defining layer PDL may partially overlap the corresponding color filter of the color filter layer CFL and the corresponding lens of the lens array LA. Accordingly, at a center of the display area DA, the light emitted from the light-emitting structure EMS may be efficiently output in a normal direction of a display surface. At an outskirt of the display area DA, the light emitted from the light-emitting structure EMS may be efficiently output in a direction inclined by an angle (e.g., predetermined angle) with respect to the normal direction of the display surface.

The overcoat layer OC may be located on the lens array LA. The overcoat layer OC may cover the optical functional layer OFL, the encapsulation layer TFE, the light-emitting structure EMS, and/or the pixel circuit layer PCL. The overcoat layer OC may include various materials suitable for protecting layers thereunder from a foreign substance, such as dust or moisture. For example, the overcoat layer OC may include at least one of an inorganic insulating layer and/or an organic insulating layer. For example, the overcoat layer OC may include epoxy, but embodiments are not limited thereto. The overcoat layer OC may have a refractive index lower than that of the lens array LA.

The cover window CW may be located on the overcoat layer OC. The cover window CW may be configured to protect layers thereunder. The cover window CW may have a refractive index that is higher than that of the overcoat layer OC. The cover window CW may include glass, but embodiments are not limited thereto. For example, the cover window CW may be an encapsulation glass configured to protect components located thereunder. In other embodiments, the cover window CW may be omitted.

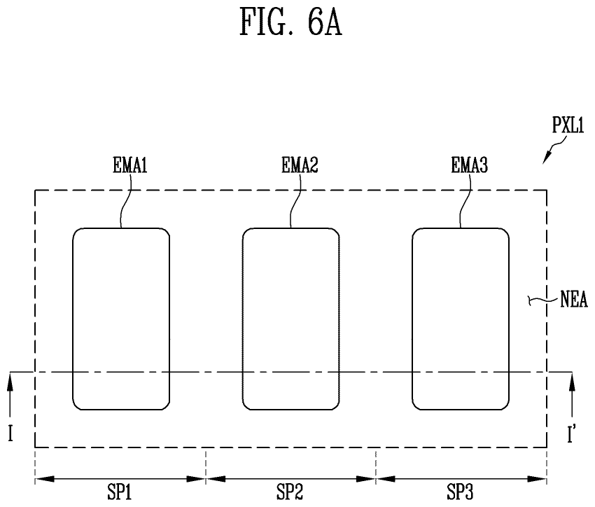

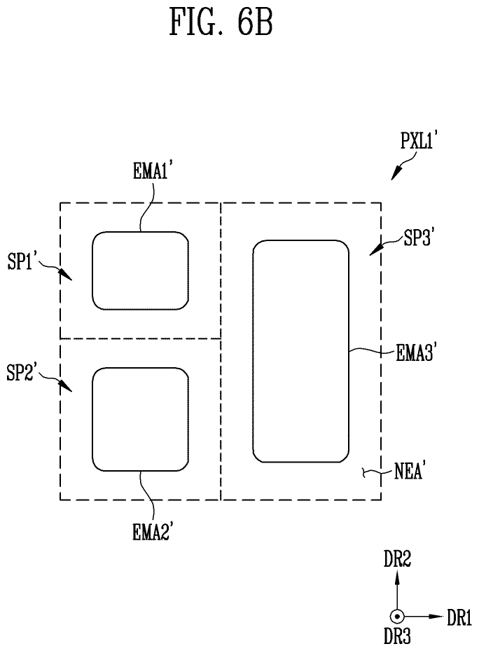

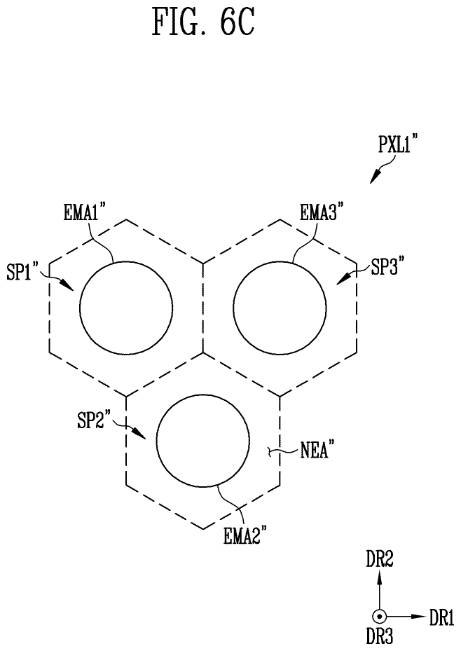

FIG. 6A is a schematic plan view illustrating one or more embodiments of one of the pixels of FIG. 5. In FIG. 6A, the first pixel PXL1 of the first and second pixels PXL1 and PXL2 of FIG. 5 is schematically shown for clear and concise description. The remaining pixels may be configured similarly to the first pixel PXL1.

Referring to FIGS. 5 and 6A, the first pixel PXL1 may include the first sub-pixel SP1, the second sub-pixel SP2, and the third sub-pixel SP3 arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The first emission area EMA1 may be an area where light is emitted from a portion of the light-emitting structure (refer to “EMS” of FIG. 5) corresponding to the first sub-pixel SP1. The second emission area EMA2 may be an area where light is emitted from a portion of the light-emitting structure EMS corresponding to the second sub-pixel SP2. The third emission area EMA3 may be an area where light is emitted from a portion of the light-emitting structure EMS corresponding to the third sub-pixel SP3. As described with reference to FIG. 5, each emission area may be understood as the opening OP of the pixel-defining layer PDL corresponding to each of the first to third sub-pixels SP1 to SP3.

FIG. 6B is a schematic plan view illustrating one or more other embodiments of one of the pixels of FIG. 5.

Referring to FIG. 6B, a first pixel PXL′ may include a first sub-pixel SP1′, a second sub-pixel SP2′, and a third sub-pixel SP3′.

The first sub-pixel SP1′ may include a first emission area EMA1′ and a non-emission area NEA′ around the first emission area EMA1′. The second sub-pixel SP2′ may include a second emission area EMA2′ and the non-emission area NEA′ around the second emission area EMA2′. The third sub-pixel SP3′ may include a third emission area EMA3′ and the non-emission area NEA′ around the third emission area EMA3′.

The first to third sub-pixels SP1′ to SP3′ may have quadrangular shapes when viewed in the third direction DR3.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area that is greater than that of the first sub-pixel SP1′. The third sub-pixel SP3′ may have an area that is greater than that of the second sub-pixel SP2′. However, embodiments are not limited thereto. For example, the first and second sub-pixels SP1′ and SP2′ may have substantially the same area, and the third sub-pixel SP3′ may have an area that is greater than that of each of the first and second sub-pixels SP1′ and SP2′. As described above, the areas of the first to third sub-pixels SP1′ to SP3′ may vary according to embodiments.

FIG. 6C is a schematic plan view illustrating still one or more other embodiments of one of the pixels of FIG. 5.

Referring to FIG. 6C, a first sub-pixel SP1″ may include a first emission area EMA1″ and a non-emission area NEA″ around the first emission area EMA1″. A second sub-pixel SP2″ may include a second emission area EMA2″ and a non-emission area NEA″ around the second emission area EMA2″. A third sub-pixel SP3″ may include a third emission area EMA3″ and a non-emission area NEA″ around the third emission area EMA3″.

The first to third sub-pixels SP1″ to SP3″ may have polygonal shapes when viewed in the third direction DR3. For example, shapes of the first to third sub-pixels SP1″ to SP3″ may be hexagonal shapes as shown in FIG. 6C.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be located in a direction inclined at an acute angle (or a diagonal direction) based on the second direction DR2 with respect to the first sub-pixel SP1″.

An arrangement of the sub-pixels shown in FIGS. 6A, 6B, and 6C are only examples, and embodiments are not limited thereto. Each pixel may include two or more sub-pixels, the sub-pixels may be arranged in various methods, each of the sub-pixels may have various shapes, and each of emission areas of the sub-pixels may also have various shapes.

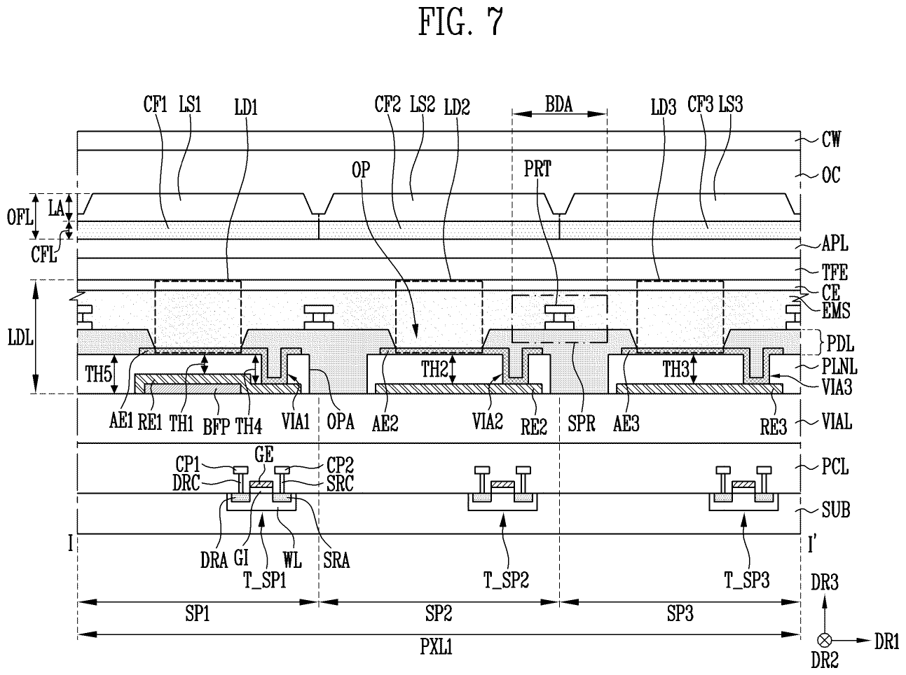

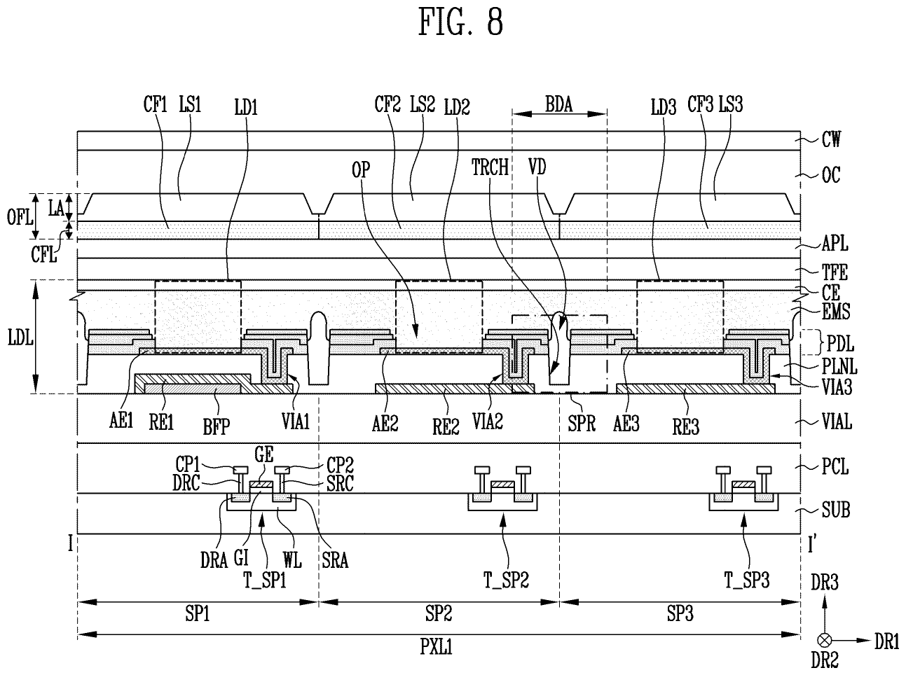

FIG. 7 is a schematic cross-sectional view illustrating one or more embodiments of a pixel taken along the line I˜I′ of FIG. 6A, and FIG. 8 is a schematic cross-sectional view illustrating one or more other embodiments of the pixel taken along the line I˜I′ of FIG. 6A. In FIG. 8, one or more other embodiments of a separator SPR is shown, and the one or more embodiments corresponding to FIG. 8 may be substantially the same as the one or more embodiments corresponding to FIG. 7 except for the separator SPR.

Referring to FIGS. 6A to 8, the first pixel PXL1 may include the first sub-pixel SP1, the second sub-pixel SP2, and the third sub-pixel SP3.

Each of the first to third sub-pixels SP1 to SP3 may include the substrate SUB, and the pixel circuit layer PCL located on the substrate SUB.

The substrate SUB may include a silicon wafer substrate formed using a semiconductor process. For example, the substrate SUB may include silicon, germanium, and/or silicon-germanium.

The pixel circuit layer PCL may be located on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit of the first sub-pixel SP1, the transistor T_SP2 of the second sub-pixel SP2 may be one of the transistors included in the sub-pixel circuit of the second sub-pixel SP2, and the transistor T_SP3 of the third sub-pixel SP3 may be one of the transistors included in the sub-pixel circuit of the third sub-pixel SP3. In FIG. 7, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in the substrate SUB, and the source area SRA and the drain area DRA may be located to be spaced apart from each other in the well WL. An area between the source area SRA and the drain area DRA in the well WL may be defined as a channel area.

The gate electrode GE may overlap the channel area between the source area SRA and the drain area DRA and may be located in the pixel circuit layer PCL. The gate electrode GE may be spaced apart from the well WL or the channel area by an insulating material, such as a gate insulating layer GI. The gate electrode GE may include a conductive material.

A plurality of layers included in the pixel circuit layer PCL may include insulating layers and conductive patterns located between the insulating layers. The conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are electrically connected to different circuit elements and/or lines, the transistor T_SP1 of the first sub-pixel SP1 may be provided as one of the transistors configuring a sub pixel circuit of the first sub-pixel SP1.

Each of the transistor T_SP2 of the second sub-pixel SP2 and the transistor T_SP3 of the third sub-pixel SP3 may be configured substantially equally to the transistor T_SP1 of the first sub-pixel SP1.

As described above, the substrate SUB and the pixel circuit layer PCL may include the circuit elements of each of the first to third sub-pixels SP1 to SP3.

A via layer VIAL (or a base layer) may be located on the pixel circuit layer PCL. The via layer VIAL may cover the pixel circuit layer PCL, and may have an overall flat (or uniform) surface. The via layer VIAL may be configured to planarize steps on the pixel circuit layer PCL. The via layer VIAL may include at least one of silicon oxide (SiOx), silicon nitride (SiNx), or silicon carbon nitride (SiCN), but embodiments are not limited thereto.

The light-emitting element layer LDL may be located on the via layer VIAL. The light-emitting element layer LDL may include first, second, and third reflective electrodes RE1, RE2, and RE3, a planarization layer PLNL, first, second, and third anode electrodes AE1, AE2, and AE3, the pixel-defining layer PDL, the light-emitting structure EMS, and the cathode electrode CE.

On the via layer VIAL, the first to third reflective electrodes RE1 to RE3 may be located in the first to third sub-pixels SP1 to SP3, respectively. For example, the first reflective electrode RE1 may be located on the via layer VIAL of the first sub-pixel SP1, the second reflective electrode RE2 may be located on the via layer VIAL of the second sub-pixel SP2, and the third reflective electrode RE3 may be located on the via layer VIAL of the third sub-pixel SP3. Each of the first to third reflective electrodes RE1 to RE3 may contact the circuit element located in the pixel circuit layer PCL through a via passing through the via layer VIAL.

The first to third reflective electrodes RE1 to RE3 may function as a full mirror for reflecting the light emitted from the light-emitting structure EMS toward the display surface (or the cover window CW). The first to third reflective electrodes RE1 to RE3 may include metal materials suitable for reflecting light. For example, the first to third reflective electrodes RE1 to RE3 may include at least one of aluminum, silver, magnesium, platinum, palladium, gold, nickel, neodymium, iridium, chromium, or titanium, and may include at least one of alloys of two or more materials selected from them. However, a material of the first to third reflective electrodes RE1 to RE3 is not limited to the above.

The first reflective electrode RE1, the second reflective electrode RE2, and the third reflective electrode RE3 may have the same thickness. For example, a thickness of each of the first reflective electrode RE1, the second reflective electrode RE2, and the third reflective electrode RE3 may be about 700 Å to about 1000 Å, or may be about 850 Å, but embodiments are not limited thereto.

According to one or more embodiments, a connection electrode may be located under each of the first to third reflective electrodes RE1 to RE3. The connection electrode may improve an electrical connection characteristic between a corresponding reflective electrode and the circuit element of the pixel circuit layer PCL. The connection electrode may be configured of multiple layers. For example, the multiple layers may include a structure in which titanium/titanium nitride/tantalum nitride are stacked, but is not limited thereto. According to one or more embodiments, a corresponding reflective electrode may be located between the layers configuring the connection electrode.

In embodiments, a buffer pattern BFP (or a sacrificial pattern) may be located under at least one of the first to third reflective electrodes RE1 to RE3. For example, the buffer pattern BFP may be located between the first reflective electrode RE1 and the via layer VIAL. The buffer pattern BFP may include an inorganic material, such as silicon carbon nitride, but embodiments are not limited thereto. Due to the buffer pattern BFP, a height of the third direction DR3 of the corresponding reflective electrode may be adjusted. For example, the buffer pattern BFP may adjust a height of the first reflective electrode RE1 between the first reflective electrode RE1 and the via layer VIAL. The first reflective electrode RE1 may entirely cover the buffer pattern BFP by covering all of an upper surface and both side surfaces (or both ends) of the buffer pattern BFP. One area of the first reflective electrode RE1 may extend to an upper surface of the via layer VIAL, which contacts the both side surfaces of the buffer pattern BFP.

In the second sub-pixel SP2, the above-described buffer pattern BFP may be omitted from between the second reflective electrode RE2 and the via layer VIAL, and the second reflective electrode RE2 may be directly located on the via layer VIAL. In addition, in the third sub-pixel SP3, the above-described buffer pattern BFP may be omitted from between the third reflective electrode RE3 and the via layer VIAL, and the third reflective electrode RE3 may be directly located on the via layer VIAL.

The first to third reflective electrodes RE1 to RE3 may function as full mirrors, and the cathode electrode CE may function as a half mirror. The light emitted from the light-emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light-emitting layer of the corresponding light-emitting structure EMS.

The first sub-pixel SP1 may have a resonance distance that is shorter than that of other sub-pixels (for example, the second and third sub-pixels SP2 and SP3) due to the buffer pattern BFP. The resonance distance adjusted as described above may allow light of a corresponding wavelength range (for example, red color) to be effectively and efficiently amplified. Accordingly, the first sub-pixel SP1 may effectively and efficiently output light of a corresponding wavelength range.

In FIG. 7, the buffer pattern BFP is provided to the first sub-pixel SP1, and is not provided to the second and third sub-pixels SP2 and SP3, but embodiments are not limited thereto. According to embodiments, the buffer pattern may also be provided in at least one of the second or third sub-pixels SP2 or SP3 to adjust a resonance distance of at least one of the second or third sub-pixels SP2 or SP3.

A thickness (or a thickness of the third direction DR3) of the buffer pattern BFP may be about 400 Å to about 600 Å, or may be about 500 Å, but embodiments are not limited thereto.

The planarization layer PLNL may planarize steps between the first to third reflective electrodes RE1 to RE3. The planarization layer PLNL may be located on the via layer VIAL and the first to third reflective electrodes RE1 to RE3. The planarization layer PLNL may generally cover the first to third reflective electrodes RE1 to RE3 and the via layer VIAL, and may have a flat surface. The planarization layer PLNL may include an insulating material. For example, the planarization layer PLNL may include an inorganic material, such as silicon oxide SiOx or silicon nitride SiNx, but embodiments are not limited thereto.

In embodiments, the planarization layer PLNL may include a via that exposes one area of the reflective electrode. For example, the planarization layer PLNL may include a first via VIA1 exposing one area of the first reflective electrode RE1, a second via VIA2 exposing one area of the second reflective electrode RE2, and a third via VIA3 exposing one area of the third reflective electrode RE3. According to embodiments, the planarization layer PLNL may include an opening area OPA formed by removing an area between adjacent sub-pixels. In this case, an upper surface of the via layer VIAL may be exposed in the opening area OPA of the planarization layer PLNL.

A first anode electrode AE1, a second anode electrode AE2, and a third anode electrode AE3 may be located on the planarization layer PLNL. For example, the first anode electrode AE1 may be located on the planarization layer PLNL to overlap the first reflective electrode RE1, the second anode electrode AE2 may be located on the planarization layer PLNL to overlap the second reflective electrode RE2, and the third anode electrode AE3 may be located on the planarization layer PLNL to overlap the third reflective electrode RE3.

The first to third anode electrodes AE1 to AE3 may have a shape that is similar to that of the first to third emission areas EMA1 to EMA3 of FIG. 6A when viewed in the third direction DR3. For example, the first anode electrode AE1 may have a shape that is similar to that of the first emission area EMA1 when viewed in the third direction DR3, the second anode electrode AE2 may have a shape that is similar to that of the second emission area EMA2 when viewed in the third direction DR3, and the third anode electrode AE3 may have a shape that is similar to that of the third emission area EMA3 when viewed in the third direction DR3, but embodiments are not limited thereto.

Each of the first to third anode electrodes AE1 to AE3 may be electrically connected to a corresponding reflective electrode. For example, the first anode electrode AE1 may be electrically connected to the first reflective electrode RE1 through the first via VIA1 passing through the planarization layer PLNL. The second anode electrode AE2 may be electrically connected to the second reflective electrode RE2 through the second via VIA2 passing through the planarization layer PLNL. The third anode electrode AE3 may be electrically connected to the third reflective electrode RE3 through the third via VIA3 passing through the planarization layer PLNL.

In embodiments, the first anode electrode AE1 may be positioned in the first via VIA1, and may be connected to the first reflective electrode RE1 by directly contacting the first reflective electrode RE1 exposed by the first via VIA1. The second anode electrode AE2 may be positioned in the second via VIA2, and may be connected to the second reflective electrode RE2 by directly contacting the second reflective electrode RE2 exposed by the second via VIA2. The third anode electrode AE3 may be positioned in the third via VIA3, and may be connected to the third reflective electrode RE3 by directly contacting the third reflective electrode RE3 exposed by the third via VIA3.

The first to third anode electrodes AE1 to AE3 may include at least one of transparent conductive materials, such as indium tin oxide (ITO), indium zinc oxide (IZO), zinc oxide (ZnOₓ), indium gallium zinc oxide (IGZO), or indium tin zinc oxide (ITZO). However, a material of the first to third anode electrodes AE1 to AE3 is not limited thereto. For example, the first to third anode electrodes AE1 to AE3 may include titanium nitride.

In embodiments, the first to third anode electrodes AE1 to AE3 may have the same or substantially similar thickness. For example, a thickness of each of the first anode electrode AE1, the second anode electrode AE2, and the third anode electrode AE3 may be about 700 Å to about 1000 Å, or may be about 850 Å, but embodiments are not limited thereto.

In one or more embodiments, a first distance TH1 (an average distance, or a shortest distance) between the first anode electrode AE1 and the first reflective electrode RE1 in the first sub-pixel SP1 may be less than a second distance TH2 between the second anode electrode AE2 and the second reflective electrode RE2 in the second sub-pixel SP2. In addition, the first distance TH1 between the first anode electrode AE1 and the first reflective electrode RE1 in the first sub-pixel SP1 may be less than a third distance TH3 between the third anode electrode AE3 and the third reflective electrode RE3 in the third sub-pixel SP3. The above-described first distance TH1 may refer to a distance between the first reflective electrode RE1 and the first anode electrode AE1 on the buffer pattern BFP.

In embodiments, the first distance TH1 may be less than the second distance TH2 and the third distance TH3, and the second distance TH2 and the third distance TH3 may be substantially equal to each other. The second distance TH2 and the third distance TH3 may be about 1.4 times to about 1.7 times, or may be about 1.9 times to about 2.4 times the first distance TH1. For example, the first distance TH1 may be about 700 Å to about 1000 Å, and the second distance TH2 and the third distance TH3 may be about 1200 Å to about 1500 Å, or may be about 1600 Å to about 2000 Å. Embodiments are not limited thereto.

A fourth distance TH4 between the first reflective electrode RE1 and the first anode electrode AE1 at a region where the first reflective electrode contacts the via layer VIAL in the first sub-pixel SP1 may be equal to the second distance TH2 and/or the third distance TH3. In each of the first to third sub-pixels SP1 to SP3, a fifth distance TH5 between the via layer VIAL and the planarization layer PLNL may be greater than the above-described first to fourth distances TH1 to TH4.

The pixel-defining layer PDL may be located on portions of the first to third anode electrodes AE1 to AE3 and the planarization layer PLNL. The pixel-defining layer PDL may include the opening OP exposing a portion of each of the first to third anode electrodes AE1 to AE3. The opening OP of the pixel-defining layer PDL may define the emission area of each of the first to third sub-pixels SP1 to SP3. The pixel-defining layer PDL may be located in the non-emission area NEA (refer to FIG. 6A) and may define the first emission area EMA1, the second emission area EMA2, and the third emission area EMA3 described with reference to FIG. 6A.

In embodiments, the pixel-defining layer PDL may include a plurality of inorganic insulating layers. Each of the plurality of inorganic insulating layers may include at least one of silicon oxide or silicon nitride. For example, with reference to FIG. 8, the pixel-defining layer PDL may include sequentially stacked first to third inorganic insulating layers, and each of the first to third inorganic insulating layers may include silicon nitride, silicon oxide, and silicon oxynitride. However, a material of the pixel-defining layer PDL is not limited to the above-described embodiments. The first to third inorganic insulating layers may have a step shape of cross-section in an area adjacent to the opening OP, but embodiments are not limited thereto.

A separator SPR may be provided in a boundary area BDA between sub-pixels neighboring each other. In other words, the separator SPR may be provided in each of the boundary areas between the sub-pixels SP of FIG. 4, but embodiments are not limited thereto.

The separator SPR may cause formation of a discontinuous portion (discontinuity) in the light-emitting structure EMS in the boundary area BDA. For example, the light-emitting structure EMS may be disconnected or bent in the boundary area BDA due to the separator SPR.

The separator SPR may be provided in or on the pixel-defining layer PDL.

In one or more embodiments, the pixel-defining layer PDL may include a protrusion pattern PRT as the separator SPR in the boundary area BDA.

As shown in FIG. 7, the protrusion pattern PRT additionally stacked on the pixel-defining layer PDL in the boundary area BDA may be provided. The protrusion pattern PRT may include a plurality of insulating patterns. For example, the protrusion pattern PRT may include first, second, and third insulating patterns sequentially stacked from the pixel-defining layer PDL. The uppermost third insulating pattern may have a greater width in the first direction DR1 than that of the second insulating pattern positioned thereunder. The second insulating pattern may be positioned between the first insulating pattern and the third insulating pattern, and may have a width in the first direction DR1 that is less than that of the first and third insulating patterns. The protrusion pattern PRT may have a cross-sectional “T” shape or “I” shape in the boundary area BDA. According to the shape of the protrusion pattern PRT, a plurality of layers included in the light-emitting structure EMS may be at least partially disconnected or bent in the boundary area BDA.

The separator SPR may be provided in various forms so that the light-emitting structure EMS may have the discontinuous portion in the boundary area BDA. In embodiments, the pixel-defining layer PDL may include one or more trenches TRCH as the separator SPR in the boundary area BDA.

As shown in FIG. 8, one or more trenches TRCH may pass through the pixel-defining layer PDL, and may partially pass through the planarization layer PLNL. In other embodiments, one or more trenches TRCH may pass through the pixel-defining layer PDL and the planarization layer PLNL, and may partially pass through the via layer VIAL. In other embodiments, one or more trenches TRCH may at least partially pass through the planarization layer PLNL and/or the via layer VIAL, and a portion of the pixel-defining layer PDL may be located in one or more trenches TRCH.

One or more trenches TRCH may be provided in the boundary area BDA. For example, one trench TRCH may be located in the boundary area BDA between the second sub-pixel SP2 and the third sub-pixel SP3. However, the disclosure is not limited thereto, and two or more trenches or three or more trenches separated from each other may be located in the boundary area BDA.

Due to the trench TRCH, in the boundary area BDA, discontinuous portions, such as a void VD, may be formed in the light-emitting structure EMS. A portion of a plurality of layers stacked in the light-emitting structure EMS may be disconnected or bent by the void VD. For example, at least one charge generation layer included in the light-emitting structure EMS may be disconnected in the void VD. As described above, portions of the light-emitting structure EMS included in the first to third sub-pixels SP1 to SP3 may be at least partially separated due to the trench TRCH.

The trench TRCH may include a portion through which at least a portion of the pixel-defining layer PDL passes, and a recessed portion of the planarization layer PLNL, and may be defined (or formed) thereby. The trench TRCH may be formed by an etching method, for example, a dry etching method or the like, but is not limited thereto. In other words, the trench TRCH may be formed by removing at least a portion of the pixel-defining layer PDL and the planarization layer PLNL in a direction from an upper surface of the pixel-defining layer PDL to a lower surface of the planarization layer PLNL.

In FIG. 8, in the boundary area BDA, one void VD is formed in the light-emitting structure EMS, but this is only an example, and embodiments are not limited thereto. For example, in the boundary area BDA, a valley of a concave shape may be formed in the light-emitting structure EMS. According to a shape of the trench TRCH, the discontinuous portions formed in the light-emitting structure EMS may be variously changed.

In embodiments, the light-emitting structure EMS may be formed through a process of vacuum deposition, inkjet printing, and the like. In this case, the same materials as the light-emitting structure EMS may be positioned on bottom surfaces of the trench TRCH adjacent to the via layer VIAL.

The light-emitting structure EMS may be located on the anode electrodes AE (refer to FIG. 5) exposed by the opening OP of the pixel-defining layer PDL. The light-emitting structure EMS may fill the opening OP of the pixel-defining layer PDL and may be located entirely across the first to third sub-pixels SP1 to SP3. As described above, the light-emitting structure EMS may be at least partially disconnected or bent in the boundary area BDA by the separator SPR. Accordingly, in case that the display panel 110 (refer to FIG. 4) is operated, a current flowing out from each of the first to third sub-pixels SP1 to SP3 to a sub-pixel adjacent thereto through layers included in the light-emitting structure EMS may be decreased. Therefore, the first, second, and third light-emitting elements LD1, LD2, and LD3 may operate with relatively high reliability.

The cathode electrode CE may be located on the light-emitting structure EMS. The cathode electrode CE may be commonly provided to the first to third sub-pixels SP1 to SP3. The cathode electrode CE may function as a half mirror that partially transmits and partially reflects the light emitted from the light-emitting structure EMS.

The first anode electrode AE1 (or a first electrode), a portion of the light-emitting structure EMS overlapping the first anode electrode AE1, and the cathode electrode CE (or a second electrode) overlapping the first anode electrode AE1 may configure the first light-emitting element LD1. The second anode electrode AE2 (or the first electrode), a portion of the light-emitting structure EMS overlapping the second anode electrode AE2, and the cathode electrode CE (or the second electrode) overlapping the second anode electrode AE2 may configure the second light-emitting element LD2. The third anode electrode AE3 (or the first electrode), a portion of the light-emitting structure EMS overlapping the third anode electrode AE3, and the cathode electrode CE (or the second electrode) overlapping the third anode electrode AE3 may configure the third light-emitting element LD3.

The encapsulation layer TFE may be located on the cathode electrode CE. The encapsulation layer TFE may reduce or prevent permeation of oxygen, moisture, and/or the like to the light-emitting element layer LDL.

The optical functional layer OFL may be located on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA.

The color filter layer CFL may include first to third color filters CF1 to CF3 respectively corresponding to the first to third sub-pixels SP1 to SP3. For example, the color filter layer CFL may include the first color filter CF1 corresponding to the first sub-pixel SP1, the second color filter CF2 corresponding to the second sub-pixel SP2, and the third color filter CF3 corresponding to the third sub-pixel SP3. The first to third color filters CF1 to CF3 may pass light of different wavelength ranges. For example, the first color filter CF1 may pass red color light, the second color filter CF2 may pass green color light, and the third color filter CF3 may pass blue color light. In this case, the first sub-pixel SP1 may be a red sub-pixel, the second sub-pixel SP2 may be a green sub-pixel, and the third sub-pixel SP3 may be a blue sub-pixel.

In embodiments, the first to third color filters CF1 to CF3 may partially overlap in the boundary area BDA. In other embodiments, the first to third color filters CF1 to CF3 may be spaced apart from each other, and a black matrix may be provided between the first to third color filters CF1 to CF3 which are spaced apart from each other.

The lens array LA may be located on the color filter layer CFL. The lens array LA may include first to third lenses LS1 to LS3 respectively corresponding to the first to third sub-pixels SP1 to SP3. For example, the lens array LA may include the first lens LS1 corresponding to the first sub-pixel SP1, the second lens LS2 corresponding to the second sub-pixel SP2, and the third lens LS3 corresponding to the third sub-pixel SP3. The first to third lenses LS1 to LS3 may improve light output efficiency by outputting the light emitted from the first to third light-emitting elements LD1 to LD3 along an intended path, respectively.

The overcoat layer OC may be located on the optical functional layer OFL, and the cover window CW may be located on the overcoat layer OC.

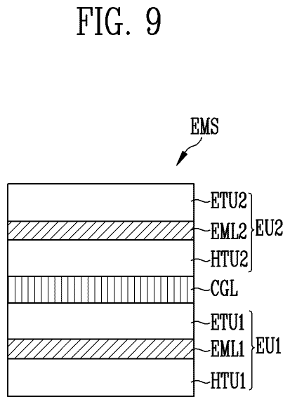

FIG. 9 is a schematic cross-sectional view illustrating one or more embodiments of the light-emitting structure EMS included in one of the first to third light-emitting elements of FIG. 7.

Referring to FIGS. 7 to 9, the light-emitting structure EMS may have a tandem structure in which first and second light-emitting components EU1 and EU2 are stacked. The light-emitting structure EMS may be configured substantially equally in each of the first to third light-emitting elements LD1 to LD3 of FIG. 7.

Each of the first and second light-emitting components EU1 and EU2 may include at least one light-emitting layer that generates light according to an applied current. The first light-emitting component EU1 may include a first light-emitting layer EML1, a first electron transport component ETU1, and a first hole transport component HTU1. The first light-emitting layer EML1 may be located between the first electron transport component ETU1 and the first hole transport component HTU1. The second light-emitting component EU2 may include a second light-emitting layer EML2, a second electron transport component ETU2, and a second hole transport component HTU2. The second light-emitting layer EML2 may be located between the second electron transport component ETU2 and the second hole transport component HTU2.

Each of the first and second hole transport components HTU1 and HTU2 may include at least one of a hole injection layer or a hole transport layer, and may further include a hole buffer layer, an electron-blocking layer, and/or the like if suitable. The first and second hole transport components HTU1 and HTU2 may have configurations equal to each other or different from each other.

Each of the first and second electron transport components ETU1 and ETU2 may include at least one of an electron injection layer or an electron transport layer, and may further include an electron buffer layer, a hole-blocking layer, and/or the like if suitable. The first and second electron transport components ETU1 and ETU2 may have configurations equal to each other or different from each other.

An intermediate layer (or a connection layer), which may be provided in a form of a charge generation layer CGL, may be located between the first light-emitting component EU1 and the second light-emitting component EU2 to connect the first light-emitting component EU1 and the second light-emitting component EU2 to each other. Hereinafter, the charge generation layer CGL is referred to as an intermediate layer. In embodiments, the intermediate layer CGL may have a stack structure of a p dopant layer and an n dopant layer. For example, the p dopant layer may include a p-type dopant, such as HAT-CN, TCNQ, and NDP-9, and the n dopant layer may include an alkali metal, an alkaline earth metal, a lanthanide metal, or a combination thereof. However, a structure (or a material) of the intermediate layer CGL is not limited to the above-described embodiments. In embodiments, the intermediate layer CGL may have conductivity by including a material with relatively high charge conductivity (or charge mobility) compared to the first and second light-emitting components EU1 and EU2.

In embodiments, the first light-emitting layer EML1 and the second light-emitting layer EML2 may generate light of different colors. Light emitted from each of the first light-emitting layer EML1 and the second light-emitting layer EML2 may be mixed and viewed as white light. For example, the first light-emitting layer EML1 may generate light of a blue color, and the second light-emitting layer EML2 may include a structure in which a first sub light-emitting layer configured to generate light of a red color and a second sub light-emitting layer configured to generate light of a green color are stacked. In this case, a functional layer configured to perform a function of transporting holes and/or blocking transport of electrons may be further located between the first and second sub light-emitting layers.

In other embodiments, the first light-emitting layer EML1 and the second light-emitting layer EML2 may generate light of the same color.

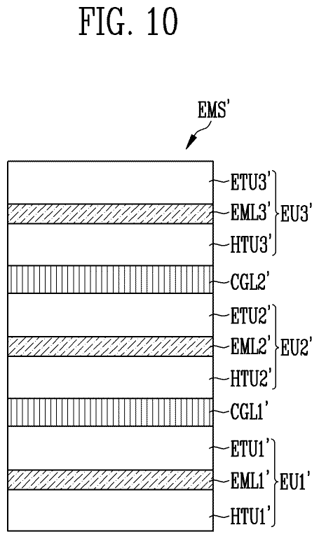

FIG. 10 is a cross-sectional view illustrating one or more other embodiments of a light-emitting structure EMS' included in one of the first to third light-emitting elements of FIG. 7.

Referring to FIGS. 7 and 10, the light-emitting structure EMS' may have a tandem structure in which first, second, and third light-emitting components EU1′, EU2, and EU3′ are stacked. The light-emitting structure EMS' may be configured substantially equally in each of the first to third light-emitting elements LD1 to LD3 of FIG. 7.

Each of the first to third light-emitting components EU1′ to EU3′ may include a light-emitting layer that generates light according to an applied current. The first light-emitting component EU1′ may include a first light-emitting layer EML1′, a first electron transport component ETU1′, and a first hole transport component HTU1′. The first light-emitting layer EML1′ may be located between the first electron transport component ETU1′ and the first hole transport component HTU1′. The second light-emitting component EU2′ may include a second light-emitting layer EML2′, a second electron transport component ETU2′, and a second hole transport component HTU2′. The second light-emitting layer EML2′ may be located between the second electron transport component ETU2′ and the second hole transport component HTU2′. The third light-emitting component EU3′ may include a third light-emitting layer EML3′, a third electron transport component ETU3′, and a third hole transport component HTU3′. The third light-emitting layer EML3′ may be located between the third electron transport component ETU3′ and the third hole transport component HTU3′.

Each of the first to third hole transport components HTU1′ to HTU3′ may include at least one of a hole injection layer or a hole transport layer, and may further include a hole buffer layer, an electron-blocking layer, and/or the like if suitable. The first to third hole transport components HTU1′ to HTU3′ may have configurations equal to each other or different from each other.

Each of the first to third electron transport components ETU1′ to ETU3′ may include at least one of an electron injection layer or an electron transport layer, and may further include an electron buffer layer, a hole-blocking layer, and the like, if suitable. The first to third electron transport components ETU1′ to ETU3′ may have configurations equal to each other or different from each other.

A first intermediate layer CGL1′ may be located between the first light-emitting component EU1′ and the second light-emitting component EU2′. A second intermediate layer CGL2′ may be located between the second light-emitting component EU2′ and the third light-emitting component EU3′. In embodiments, the first intermediate layer CGL1′ and the second intermediate layer CGL2′ may have conductivity by including a material with relatively high charge conductivity (or charge mobility) compared to the first light-emitting component EU1′, the second light-emitting component EU2′, and the third light-emitting component EU3′.

In embodiments, the first to third light-emitting layers EML1′ to EML3′ may generate light of different colors. Light emitted from each of the first to third light-emitting layers EML1′ to EML3′ may be mixed, and may be viewed as white light. For example, the first emitting layer EML1′ may generate light of a blue color, the second emitting layer EML2′ may generate light of a green color, and the third emitting layer EML3′ may generate light of a red color.

In other embodiments, two or more of the first to third light-emitting layers EML1′ to EML3′ may generate light of the same color.

Differently from that shown in FIGS. 9 and 10, the light-emitting structure EMS of FIG. 7 may include one light-emitting component in each of the first to third light-emitting elements LD1 to LD3. At this time, the light-emitting component included in each of the first to third light-emitting elements LD1 to LD3 may be configured to emit light of different colors. For example, the light-emitting component of the first light-emitting element LD1 may emit the light of the red color, the light-emitting component of the second light-emitting element LD2 may emit the light of the green light, and the light-emitting component of the third light-emitting element LD3 may emit the light of the blue color. In this case, differently from that shown in FIG. 7, the light-emitting components of the first to third sub-pixels SP1 to SP3 may be separated from each other and may be located in the corresponding opening OP of the pixel-defining layer PDL. As described above, in case that the light-emitting component of the first sub-pixel SP1, the light-emitting component of the second sub-pixel SP2, and the light-emitting component of the third sub-pixel SP3 are located in the corresponding opening OP of the pixel-defining layer PDL, at least a portion of the first to third color filters CF1 to CF3 may be omitted.

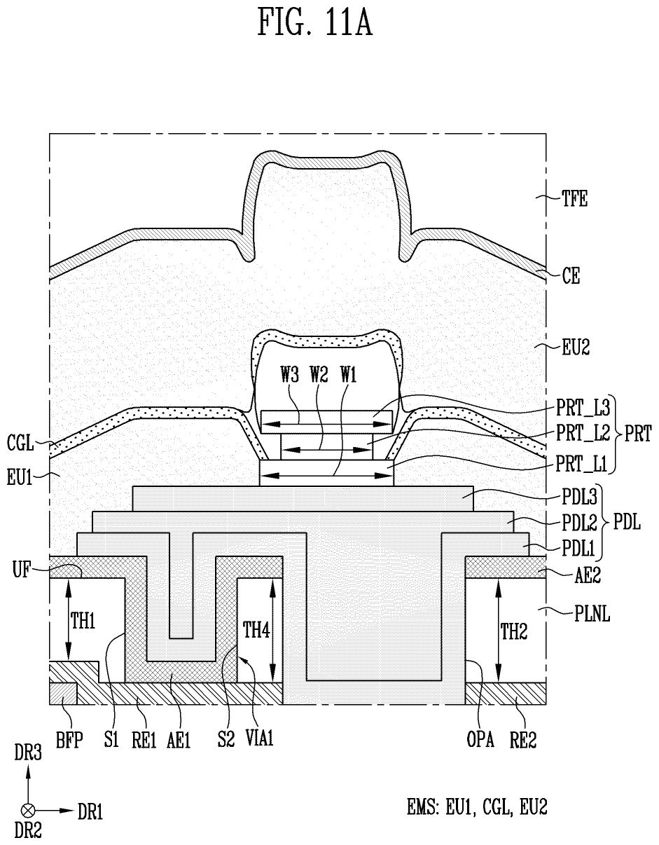

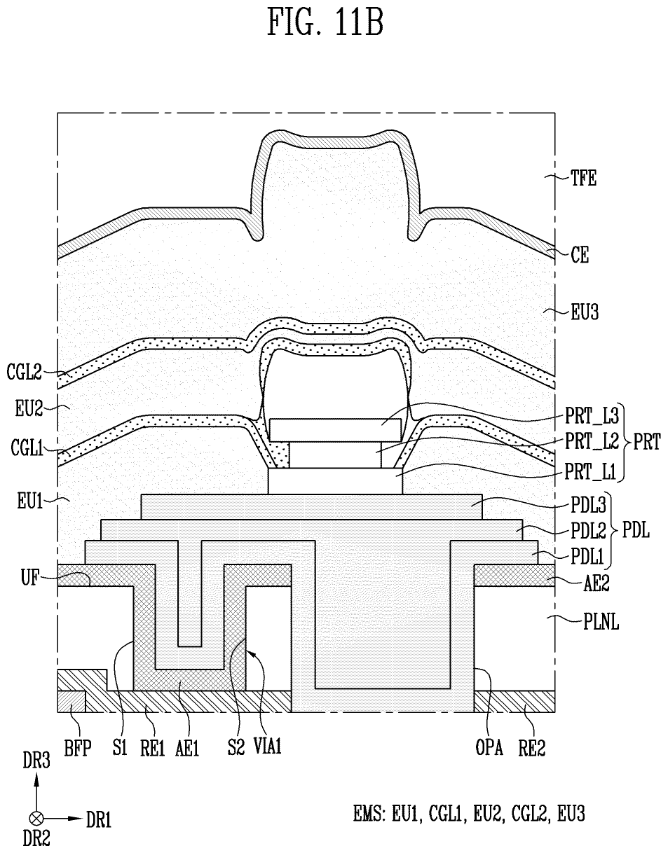

FIGS. 11A and 11B are schematic enlarged cross-sectional views of a portion of the display device of FIG. 7.

In FIGS. 11A and 11B, the planarization layer PLNL, the anode electrodes AE1 and AE2, the pixel-defining layer PDL, the light-emitting structure EMS, the cathode electrode CE, and the encapsulation layer TFE in a partial area (for example, the boundary between the first sub-pixel (refer to “SP1” of FIG. 7) and the second sub-pixel (refer to “SP2” of FIG. 7)) including the protrusion pattern PRT are shown.

Referring to FIGS. 7, 11A, and 11B, the planarization layer PLNL may be located on the first reflective electrode RE1 and the second reflective electrode RE2.

The first reflective electrode RE1 may be located on the buffer pattern BFP and the via layer (refer to “VIAL” of FIG. 7), and the second reflective electrode RE2 may be located on the via layer VIAL. The first reflective electrode RE1 on the buffer pattern BFP may be more adjacent to an upper surface UF of the planarization layer PLNL in a thickness direction (or the third direction DR3) of the planarization layer PLNL as compared to the second reflective electrode RE2. That is, the first reflective electrode RE1 on the buffer pattern BFP may protrude in an upper direction (or the third direction DR3) as compared to the second reflective electrode RE2. Accordingly, the separation distance TH1 between the first reflective electrode RE1 on the buffer pattern BFP and the upper surface UF of the planarization layer PLNL (or the first anode electrode AE1) may be less than the separation distance TH2 between the second reflective electrode RE2 and the upper surface UF of the planarization layer PLNL (or the second anode electrode AE2). The separation distance TH4 between the first reflective electrode RE1 on the via layer VIAL and the upper surface UF of the planarization layer PLNL may be substantially equal to the separation distance TH2 between the second reflective electrode RE2 and the upper surface UF of the planarization layer PLNL.

The planarization layer PLNL may include a via (e.g., a “contact hole” or a “through hole”) that exposes one area of each reflective electrode. For example, the planarization layer PLNL may include the first via VIA1 exposing one area of the first reflective electrode RE1. One area of the first reflective electrode RE1 may overlap the pixel-defining layer PDL. That is, the first via VIA1 and one area of the first reflective electrode RE1 exposed by the first via VIA1 may be positioned in the non-emission area (refer to “NEA” of FIG. 6A).

The planarization layer PLNL may further include a first side surface S1 and a second side surface S2 facing each other with the first via VIA1 interposed therebetween. The first side surface S1 may be a first sidewall of the first via VIA1, and the second side surface S2 may be a second sidewall of the first via VIA1. The first side surface S1 and the second side surface S2 may be connected to the upper surface UF of the planarization layer PLNL on which the first anode electrode AE1 is located.

In embodiments, the first anode electrode AE1 may be inserted into the first via VIA1, and may be located on each of the first and second side surfaces S1 and S2 of the planarization layer PLNL and the first reflective electrode RE1. For example, the first anode electrode AE1 may be located on the first sidewall and the second sidewall of the first via VIA1, and may be located on the first reflective electrode RE1 exposed by the first via VIA1.

The planarization layer PLNL may further include the opening area OPA formed by removing a portion of the boundary area BDA, but embodiments are not limited thereto. According to one or more embodiments, a portion of the planarization layer PLNL may not be removed in the boundary area BDA.

The pixel-defining layer PDL may be located on the planarization layer PLNL.

The pixel-defining layer PDL may include a first inorganic insulating layer PDL1 (or a first inorganic layer), a second inorganic insulating layer PDL2 (or a second inorganic layer), a third inorganic insulating layer PDL3 (or a third inorganic layer) sequentially stacked along the third direction DR3, but embodiments are not limited thereto. According to one or more embodiments, the pixel-defining layer PDL may further include additional inorganic insulating layers in addition to the inorganic insulating layers described above.

The first inorganic insulating layer PDL1 and the third inorganic insulating layer PDL3 may include silicon nitride, and the second inorganic insulating layer PDL2 may include silicon oxide. However, a material of the first to third inorganic insulating layers PDL1 to PDL3 is not limited to the above. The pixel-defining layer PDL including the first, second, and third inorganic insulating layers PDL1, PDL2, and PDL3 may have a step shape of cross-section in an area adjacent to the opening (refer to “OP” of FIG. 7), but one or more embodiments are not limited thereto. According to one or more embodiments, the pixel-defining layer PDL may not have a step shape of cross-section in the area adjacent to the opening OP.

The first inorganic insulating layer PDL1 may cover the planarization layer PLNL and the first and second anode electrodes AE1 and AE2. In one or more embodiments, the first inorganic insulating layer PDL1 may be located on the first anode electrode AE1 inserted into the first via VIA1, and may cover the first anode electrode AE1. In addition, the first inorganic insulating layer PDL1 may be positioned in the opening area OPA of the planarization layer PLNL, and may cover the via layer VIAL exposed by the opening area OPA. In addition, the first inorganic insulating layer PDL1 may be located on both side surfaces of the via layer VIAL facing each other with the opening area OPA interposed therebetween.

The second inorganic insulating layer PDL2 may be located on the first inorganic insulating layer PDL1. An upper surface of the second inorganic insulating layer PDL2 may be planarized through a planarization process to smooth steps due to configurations located under the second inorganic insulating layer PDL2. For example, the upper surface of the second inorganic insulating layer PDL2 may be planarized through a chemical mechanical polishing (CMP) process. However, embodiments are not limited thereto. According to one or more embodiments, to reduce a process dispersion defect due to the CMP process, an etching process using a mask may be performed instead of the CMP process. The second inorganic insulating layer PDL2 may have a width that is less than that of the first inorganic insulating layer PDL1 in the first direction DR1 in the boundary area BDA.

The third inorganic insulating layer PDL3 may be located on the second inorganic insulating layer PDL2. The third inorganic insulating layer PDL3 may be positioned at the uppermost portion of the pixel-defining layer PDL, and may have a width that is less than that of the second inorganic insulating layer PDL2 in the first direction DR1 in the boundary area BDA.

The protrusion pattern PRT may be positioned between the first sub-pixel SP1 and the second sub-pixel SP2. For example, the protrusion pattern PRT protruding in the third direction DR3 in the boundary area BDA (or the non-emission area NEA) between the first sub-pixel SP1 and the second sub-pixel SP2 may be positioned.

The protrusion pattern PRT may form a step on the upper surface of the pixel-defining layer PDL for disposition of the first light-emitting component EU1 in the boundary area BDA, and may disconnect the first light-emitting component EU1 (and the intermediate layer CGL) in the boundary area BDA.

The protrusion pattern PRT may include sequentially stacked inorganic insulating patterns. For example, the protrusion pattern PRT may include a first inorganic insulating pattern PRT_L1 (or a first insulating pattern), a second inorganic insulating pattern PRT_L2 (or a second insulating pattern), and a third inorganic insulating pattern PRT_L3 (or a third insulating pattern) sequentially stacked on the third inorganic insulating layer PDL3 of the pixel-defining layer PDL. The first inorganic insulating pattern PRT_L1 and the third inorganic insulating pattern PRT_L3 may include silicon oxide, and the second inorganic insulating pattern PRT_L2 may include silicon nitride, but embodiments are not limited thereto.

In one or more embodiments, based on the first direction DR1, a width W3 of the third inorganic insulating pattern PRT_L3 may be greater than a width W2 of the second inorganic insulating pattern PRT_L2. In addition, the width W2 of the second inorganic insulating pattern PRT_L2 may be less than or equal to a width W1 of the first inorganic insulating pattern PRT_L1. In this case, the protrusion pattern PRT may have an overhang structure, inverse tapered shape, a cross-sectional “T” shape, or a cross-sectional “I” shape. The width W1 of the first inorganic insulating pattern PRT_L1 and the width W3 of the third inorganic insulating pattern PRT_L3 may be equal to each other.

According to a shape of the protrusion pattern PRT, a portion of the light-emitting structure EMS may be disconnected in the boundary area BDA.

The light-emitting structure EMS may be located on the pixel-defining layer PDL and the protrusion pattern PRT. The light-emitting structure EMS may include the first light-emitting component EU1 and the second light-emitting component EU2. The light-emitting structure EMS may include the first light-emitting component EU1, the intermediate layer CGL, and the second light-emitting component EU2. The first light-emitting component EU1 may be the same as the first light-emitting component EU1 described with reference to FIG. 9, the second light-emitting component EU2 may be the same as the second light-emitting component EU2 described with reference to FIG. 9, and the intermediate layer CGL may be the same as the intermediate layer CGL described with reference to FIG. 9. Each of the first and second light-emitting parts EU1 and EU2 may include a charge transport component, a light-emitting layer, an electron transport component, a buffer layer, and/or the like including a material with charge conductivity relatively lower than that of the intermediate layer CGL.

The first light-emitting component EU1 may be located on the pixel-defining layer PDL and the protrusion pattern PRT. The first light-emitting component EU1 may include a disconnection portion separated in the boundary area BDA due to a shape of the protrusion pattern PRT. In this case, the first light-emitting component EU1 of the first sub-pixel SP1 may be separated from the first light-emitting component EU1 of the second sub-pixel SP2.

The intermediate layer CGL may be located on the first light-emitting component EU1. Similarly to the first light-emitting component EU1, the intermediate layer CGL may include a disconnection portion separated in the boundary area BDA by the shape of the protrusion pattern PRT. In this case, the intermediate layer CGL of the first sub-pixel SP1 may be separated from the intermediate layer CGL of the second sub-pixel SP2. In this case, a phenomenon, in which a current is leaked from one sub-pixel to another sub-pixel adjacent thereto through the intermediate layer CGL, may be reduced or prevented, and the sub-pixel may operate with high reliability. In addition, in case that the intermediate layer CGL has the disconnection portion in the boundary area BDA, color mixing between adjacent sub-pixels may be reduced or prevented.

The second light-emitting component EU2 may be formed on the intermediate layer CGL and the protrusion pattern PRT. The second light-emitting component EU2 may be formed on the intermediate layer CGL and the protrusion pattern PRT to have a relatively thick thickness. Accordingly, the second light-emitting component EU2 may not be disconnected in the boundary area BDA by a shape of the protrusion pattern PRT. In this case, the second light-emitting component EU2 of the first sub-pixel SP1 and the second light-emitting component EU2 of the second sub-pixel SP2 may be connected.

As described above, the first light-emitting component EU1 and the intermediate layer CGL may be disconnected in the boundary area BDA by the protrusion pattern PRT. The second light-emitting component EU2 and the cathode electrode CE may be continuous without being disconnected in the boundary area BDA.

The first light-emitting component EU1 and the intermediate layer CGL might not be formed (or deposited) on a side surface of the protrusion pattern PRT, and each of the first light-emitting component EU1 and the intermediate layer CGL may be disconnected at an edge of the protrusion pattern PRT. Based on the third direction DR3, a thickness of the first light-emitting component EU1 may be less than a thickness of the protrusion pattern PRT, and a thickness of the second light-emitting component EU2 may be greater than the thickness of the protrusion pattern PRT. In this case, at the edge of the protrusion pattern PRT, each of the first light-emitting component EU1 and the intermediate layer CGL may be disconnected or discontinuous, and each of the second light-emitting component EU2 and the cathode electrode CE may be connected or continuous.

As shown in FIG. 11B, the light-emitting structure EMS may include the first light-emitting component EU1, a first intermediate layer CGL1 (or a first charge generation layer), the second light-emitting component EU2, a second intermediate layer CGL2 (or a second charge generation layer), and the third light-emitting component EU3. The first intermediate layer CGL1 may be located between the first light-emitting component EU1 and the second light-emitting component EU2, and the second intermediate layer CGL2 may be located between the second light-emitting component EU2 and the third light-emitting component EU3.

In embodiments, each of the first to third light-emitting components EU1 to EU3 may include a light-emitting layer that generates light according to an applied current. The first light-emitting component EU1 may be the same as the first light-emitting component EU1′ described with reference to FIG. 10, the second light-emitting component EU2 may be the same as the second light-emitting component EU2′ described with reference to FIG. 10, and the third light-emitting component EU3 may be the same as the third light-emitting component EU3′ described with reference to FIG. 10.

The first, second, and third light-emitting components EU1, EU2, and EU3 may include a charge transport component, a light-emitting layer, an electron transport component, a buffer layer, and/or the like including a material with relatively low charge conductivity (or charge mobility) compared to the first and second intermediate layers CGL1 and CGL2.

Each of the first light-emitting component EU1 and the first intermediate layer CGL1 may include a disconnection portion separated in the boundary area BDA due to the shape of the protrusion pattern PRT. In this case, the first light-emitting component EU1 of the first sub-pixel SP1 and the first light-emitting component EU1 of the second sub-pixel SP2 may be separated from each other, and the first intermediate layer CGL1 of the first sub-pixel SP1 and the first intermediate layer CGL1 of the second sub-pixel SP2 may be separated from each other.

The second light-emitting component EU2 located on the first intermediate layer CGL1 may not be affected by, or may be minimally affected by, the shape of the protrusion pattern PRT, and may not be disconnected in the boundary area BDA. In this case, the second light-emitting component EU2 of the first sub-pixel SP1 and the second light-emitting component EU2 of the second sub-pixel SP2 may be connected.

The second intermediate layer CGL2 may have a profile corresponding to a profile of the second light-emitting component EU2 located under the second intermediate layer CGL2. Accordingly, the second intermediate layer CGL2 may not be affected by the shape of the protrusion pattern PRT and may not be disconnected in the boundary area BDA. In this case, the second intermediate layer CGL2 of the first sub-pixel SP1 and the second intermediate layer CGL2 of the second sub-pixel SP2 may be connected.

The third light-emitting component EU3 may be formed on the second intermediate layer CGL2 to have a thickness that is relatively thicker than that of the second light-emitting component EU2. Accordingly, the third light-emitting component EU3 may not be disconnected in the boundary area BDA due to the shape of the protrusion pattern PRT. In this case, the third light-emitting component EU3 of the first sub-pixel SP1 and the third light-emitting component EU3 of the second sub-pixel SP2 may be connected.

The cathode electrode CE may be located on the third light-emitting component EU3. The cathode electrode CE may be formed of metal including a conductive material. In embodiments, the third light-emitting component EU3 may be relatively thicker than the first and second light-emitting components EU1 and EU2. A thickness of the third light-emitting component EU3 may be a gap between the second intermediate layer CGL2 and the cathode electrode CE. In other words, the thickness of the third light-emitting component EU3 corresponding to the gap between the second intermediate layer CGL2 and the cathode electrode CE may be greater than a gap (or the thickness of the second light-emitting component EU2) between the first intermediate layer CGL1 and the second intermediate layer CGL2. This is because, for reducing or preventing the likelihood of a defect occurring due to a short circuit with the second intermediate layer CGL2 having conductivity by including a material with high charge conductivity (or charge mobility), and for reducing or preventing the likelihood of the cathode electrode CE being disconnected due to a step of configurations (for example, the second intermediate layer CGL2, the second light-emitting component EU2, the first intermediate layer CGL1, and the first light-emitting component EU1) positioned thereunder. In other words, the gap between the cathode electrode CE and the second intermediate layer CGL2 may be further secured by the third light-emitting component EU3 having a relatively thick thickness, thereby reducing or preventing the likelihood of a defect in which the cathode electrode CE and the second intermediate layer CGL2 are shorted. In addition, because a step between configurations positioned under the third light-emitting component EU3 may be smoothened by the third light-emitting component EU3, a step coverage of the cathode electrode CE located on the third light-emitting component EU3 may be improved, thereby the likelihood of a defect that the cathode electrode CE is disconnected on the trench TRCH may be reduced or prevented.

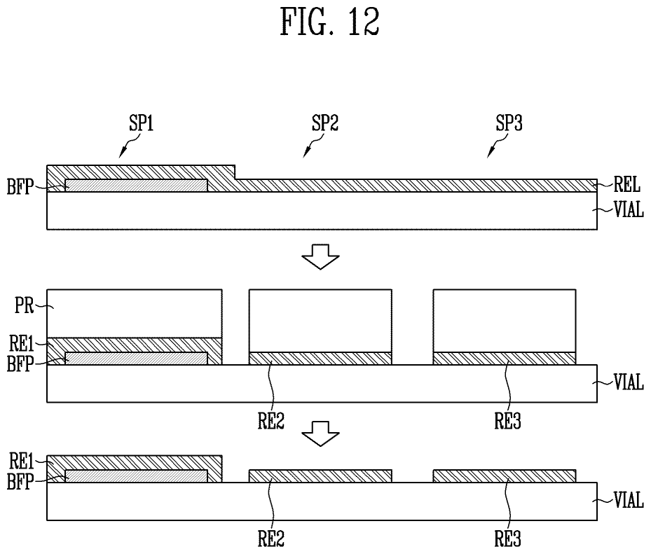

FIGS. 12 to 16 are schematic cross-sectional views illustrating a method of manufacturing a display device according to embodiments. The display device according to the one or more embodiments corresponding to FIG. 7 may be manufactured through the method of manufacturing the display device of FIGS. 12 to 16. In FIGS. 12 to 16, a description overlapping the one or more embodiments corresponding to FIG. 7 is omitted for convenience of description.

Referring to FIGS. 7 and 12, the buffer pattern BFP is formed on the via layer VIAL of the first sub-pixel SP1 (or a first sub-pixel area). The buffer pattern BFP is not formed on the via layer VIAL of each of the second and third sub-pixels SP2 and SP3.

A reflective electrode layer REL may be formed entirely on the buffer pattern BFP and the via layer VIAL. The reflective electrode layer REL may cover the via layer VIAL and the buffer pattern BFP. The reflective electrode layer REL may be a base material of the first reflective electrode RE1, the second reflective electrode RE2, and the third reflective electrode RE3.

Thereafter, a photoresist PR may be formed on the reflective electrode layer REL. The photoresist PR may be formed in each of the first to third sub-pixels SP1 to SP3, and may be omitted, or may be removed, in an area (or the boundary area (refer to “BDA” of FIG. 7)) between the first to third sub-pixels SP1 to SP3.

Thereafter, the first reflective electrode RE1, the second reflective electrode RE2, and the third reflective electrode RE3 may be formed from the reflective electrode layer REL using the photoresist PR. For example, one area of the reflective electrode layer REL may be removed from the area between the first to third sub-pixels SP1 to SP3 through an etching process using the photoresist PR as a mask, and the first reflective electrode RE1, the second reflective electrode RE2, and the third reflective electrode RE3 may be separated from each other.

Thereafter, the photoresist PR may be removed.

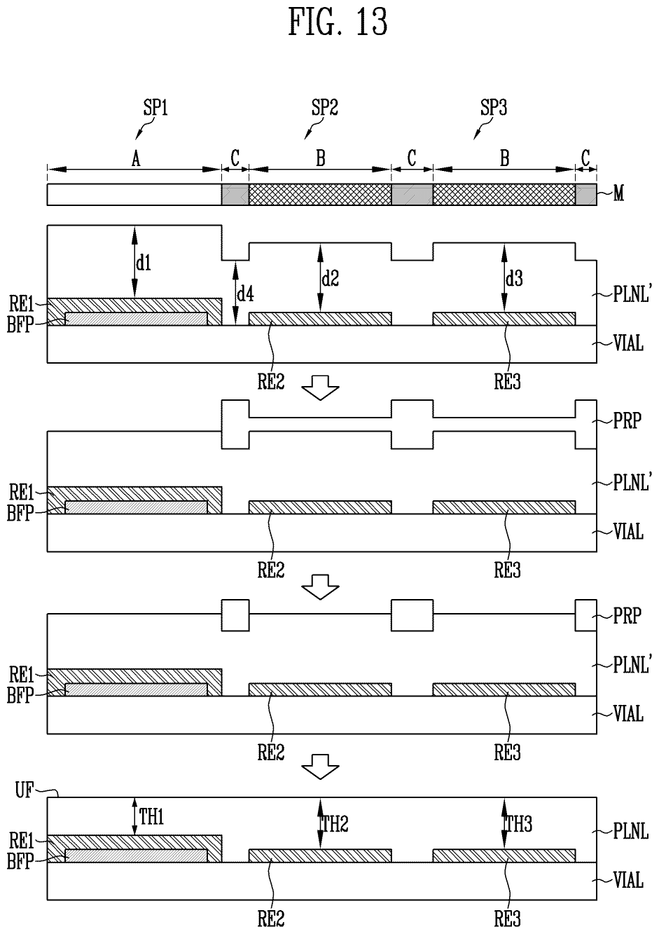

Referring to FIG. 13, the planarization layer PLNL covering the first to third reflective electrodes RE1 to RE3, and having the flat upper surface UF is formed.

A planarization material layer PLNL′ may be formed entirely on the first to third reflective electrodes RE1 to RE3. The planarization material layer PLNL′ may be a base material of the planarization layer PLNL.

The planarization material layer PLNL′ may have substantially the same thickness, regardless of location, in a thickness direction of the via layer VIAL, and may have an upper surface that is not uniform for each area. For example, a thickness d1 of the planarization material layer PLNL′ on the first reflective electrode RE1, a thickness d2 of the planarization material layer PLNL′ on the second reflective electrode RE2, a thickness d3 of the planarization material layer PLNL′ on the third reflective electrode RE3, and a thickness d4 of the planarization material layer PLNL′ on the via layer VIAL may be substantially equal to each other. However, embodiments are not limited thereto.

As the planarization material layer PLNL′ has the same thickness regardless of the area, the planarization material layer PLNL′ on the first reflective electrode RE1 positioned on the buffer pattern BFP may protrude in an upper direction. That is, the planarization material layer PLNL′ may have a non-uniform upper surface (or surface).

A photoresist is entirely deposited on the planarization material layer PLNL′, and a mask M is located thereon. The mask M may include a halftone mask capable of adjusting light transmittance for each area.

The mask M may include a first portion A, a second portion B, and a third portion C. The first portion A may be a transmissive portion that completely transmits light, the second portion B may be a semi-transmissive portion with an adjusted light transmittance, and the third portion C may be a blocking portion that completely blocks light. The first portion A may correspond to the planarization material layer PLNL′ on the first reflective electrode RE1, the second portion B may correspond to the planarization material layer PLNL′ on the second and third reflective electrodes RE2 and RE3, and the third portion C may correspond to the planarization material layer PLNL′ on the via layer VIAL.

A photoresist pattern PRP is formed by performing exposure through the mask M, and through developing the photoresist. The photoresist pattern PRP may be positioned on the planarization material layer PLNL′ on the via layer VIAL, the second reflective electrode RE2, and the third reflective electrode RE3. The photoresist pattern PRP is not positioned on the planarization material layer PLNL′ on the first reflective electrode RE1. Accordingly, the planarization material layer PLNL′ on the first reflective electrode RE1 may be exposed to an outside.

The photoresist pattern PRP may have a thin thickness on the planarization material layer PLNL′ on the second and third reflective electrodes RE2 and RE3, and may have a thick thickness on the via layer VIAL. That is, the photoresist having a relatively thin thickness on the planarization material layer PLNL′ on the second and third reflective electrodes RE2 and RE3, having a relatively thick thickness on the planarization material layer PLNL′ on the via layer VIAL, and being removed on the planarization material layer PLNL′ on the first reflective electrode RE1, may become the photoresist pattern PRP.

Thereafter, a portion of the planarization material layer PLNL′ on the first reflective electrode RE1 exposed to the outside is removed by performing dry etching using the photoresist pattern PRP as an etch mask. At this time, an upper surface of the planarization material layer PLNL′ on the first reflective electrode RE1 may coincide with an upper surface of the planarization material layer PLNL′ on the second and third reflective electrodes RE2 and RE3.

Thereafter, the photoresist pattern PRP may be ashed to thin the overall thickness of the photoresist pattern PRP. At this time, the photoresist pattern PRP positioned on the planarization material layer PLNL′ on the second and third reflective electrodes RE2, RE3 may be removed, and thus the planarization material layer PLNL′ may be exposed to the outside. A portion of the planarization material layer PLNL′ on the first to third reflective electrodes RE1 to RE3 exposed to the outside is removed by performing dry etching using the photoresist pattern PRP as an etch mask. At this time, the upper surface of the planarization material layer PLNL′ on the first to third reflective electrodes RE1 to RE3 may coincide with the upper surface of the planarization material layer PLNL′ on the via layer VIAL.

Thereafter, the planarization layer PLNL having the flat (or uniform) upper surface UF may be formed by removing a remaining photoresist pattern PRP. A separation distance TH1 between the first reflective electrode RE1 and the upper surface UF of the planarization layer PLNL may be less than the separation distance TH2 between the second reflective electrode RE2 and the upper surface UF of the planarization layer PLNL, and may be less than the separation distance TH3 between the third reflective electrode RE3 and the upper surface UF of the planarization layer PLNL. The separation distance TH2 between the second reflective electrode RE2 and the upper surface UF of the planarization layer PLNL may be substantially equal to the separation distance TH3 between the third reflective electrode RE3 and the upper surface UF of the planarization layer PLNL.

In a process of forming the planarization layer PLNL, a photoresist process using the mask M is performed without using a CMP process. Accordingly, a process dispersion defect that may occur during the CMP process may be reduced.

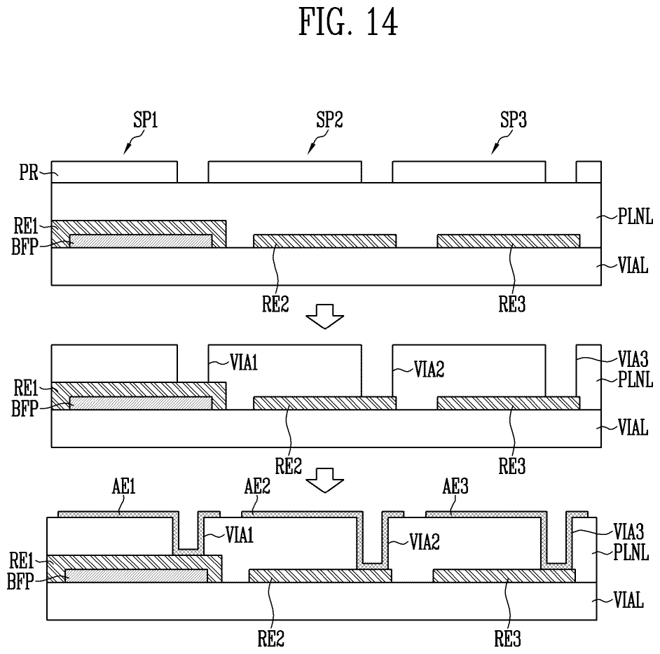

Referring to FIG. 14, the first anode electrode AE1, the second anode electrode AE2, and the third anode electrode AE3 are formed on the planarization layer PLNL.

In one or more embodiments, the photoresist PR may be formed on the planarization layer PLNL, and vias partially exposing the reflective electrodes RE1, RE2, and RE3 may be formed on the planarization layer PLNL using the photoresist PR as a mask. The vias may include the first via VIA1 exposing one area of the first reflective electrode RE1, the second via VIA2 exposing one area of the second reflective electrode RE2, and the third via VIA3 exposing one area of the third reflective electrode RE3. After the first to third vias VIA1 to VIA3 are formed, the photoresist PR may be removed. At this time, the planarization layer PLNL may include a first side surface and a second side surface facing each other with each via interposed therebetween. The first side surface may be a first sidewall of each of the first to third vias VIA1 to VIA3, and the second side surface may be a second sidewall of each of the first to third vias VIA1 to VIA3.

Thereafter, the first anode electrode AE1, the second anode electrode AE2, and the third anode electrode AE3 are formed on the planarization layer PLNL.

The first anode electrode AE1 may be located on the planarization layer PLNL in the first sub-pixel SP1, and may be inserted into the first via VIA1 to be physically and/or electrically connected to the first reflective electrode RE1. The second anode electrode AE2 may be located on the planarization layer PLNL in the second sub-pixel SP2, and may be inserted into the second via VIA2 to be physically and/or electrically connected to the second reflective electrode RE2. The third anode electrode AE3 may be located on the planarization layer PLNL in the third sub-pixel SP3, and may be inserted into the third via VIA3 to be physically and/or electrically connected to the third reflective electrode RE3.

The first anode electrode AE1 may be inserted into the first via VIA1 and located on the first reflective electrode RE1, and may be located on the first and second sidewalls of the first via VIA1. The first anode electrode AE1 may not be entirely inserted into the first via VIA1, but may be located only on the first and second sidewalls. Accordingly, the first anode electrode AE1 located on the first sidewall, and the second anode electrode AE2 located on the second sidewall, may be spaced apart from each other at a distance (e.g., predetermined distance). However, embodiments are not limited thereto.

The second anode electrode AE2 may be inserted into the second via VIA2, and located on the second reflective electrode RE2, and may be located on the first and second sidewalls of the second via VIA2. The second anode electrode AE2 may not be entirely inserted into the second via VIA2, but may be located only on the first and second sidewalls. Accordingly, the second anode electrode AE2 located on the first sidewall, and the second anode electrode AE2 located on the second sidewall, may be spaced apart from each other at a distance (e.g., predetermined distance).

The third anode electrode AE3 may be inserted into the third via VIA3 and located on the third reflective electrode RE3, and may be located on the first and second sidewalls of the third via VIA3. The third anode electrode AE3 may not be entirely inserted into the third via VIA3, but may be located only on the first and second sidewalls. Accordingly, the third anode electrode AE3 located on the first sidewall, and the third anode electrode AE3 located on the second sidewall, may be spaced apart from each other at a distance (e.g., predetermined distance).

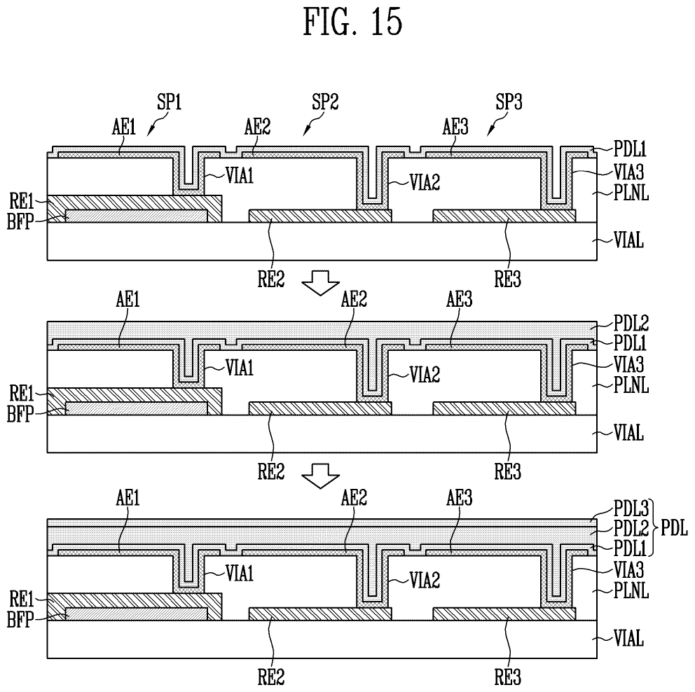

Referring to FIG. 15, the pixel-defining layer PDL is formed on the planarization layer PLNL and the anode electrodes AE1 to AE3. The pixel-defining layer PDL may include the first inorganic insulating layer PDL1, the second inorganic insulating layer PDL2, and the third inorganic insulating layer PDL3 sequentially stacked.

In one or more embodiments, the pixel-defining layer PDL may be formed entirely on the planarization layer PLNL. The pixel-defining layer PDL may cover the anode electrodes AE1 to AE3.

The first inorganic insulating layer PDL1 is formed on the planarization layer PLNL and the anode electrodes AE1 to AE3. The first inorganic insulating layer PDL1 may be inserted into the first to third vias VIA1 to VIA3.

The second inorganic insulating layer PDL2 is formed on the first inorganic insulating layer PDL1. The second inorganic insulating layer PDL2 may have a thickness that is thicker than that of the first inorganic insulating layer PDL1, and may have a gentle profile. The second inorganic insulating layer PDL2 may smooth a step due to configurations located under the second inorganic insulating layer PDL2. The second inorganic insulating layer PDL2 may be inserted into the first to third vias VIA1 to VIA3 to entirely fill the first to third vias VIA1 to VIA3.

The third inorganic insulating layer PDL3 is formed on the second inorganic insulating layer PDL2.

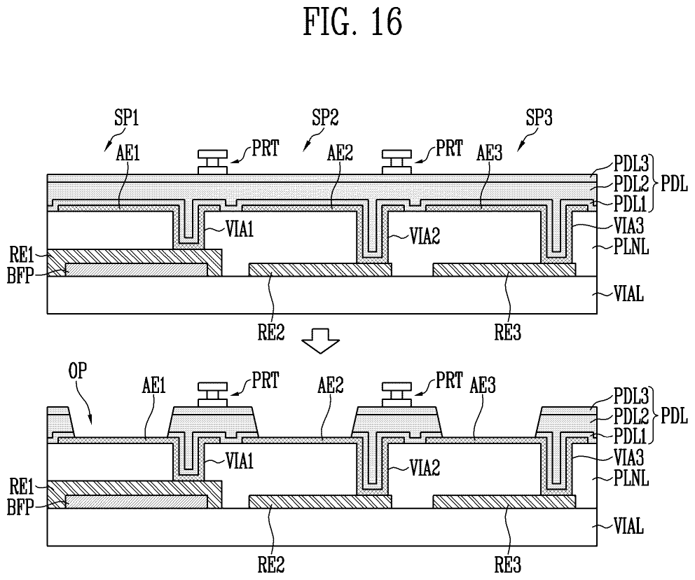

Referring to FIG. 16, the protrusion pattern PRT is formed on the pixel-defining layer PDL. The protrusion pattern PRT may function as the separator (refer to “SPR” of FIG. 7).

Thereafter, a portion of the pixel-defining layer PDL is removed to form the opening(s) OP exposing the first to third anode electrodes AE1 to AE3.

Thereafter, the remaining configurations shown in FIG. 7, for example, the light-emitting structure EMS, the cathode electrode CE, and the encapsulation layer TFE, may be sequentially formed. Through this, the display device according to the one or more embodiments corresponding to FIG. 7 may be manufactured.

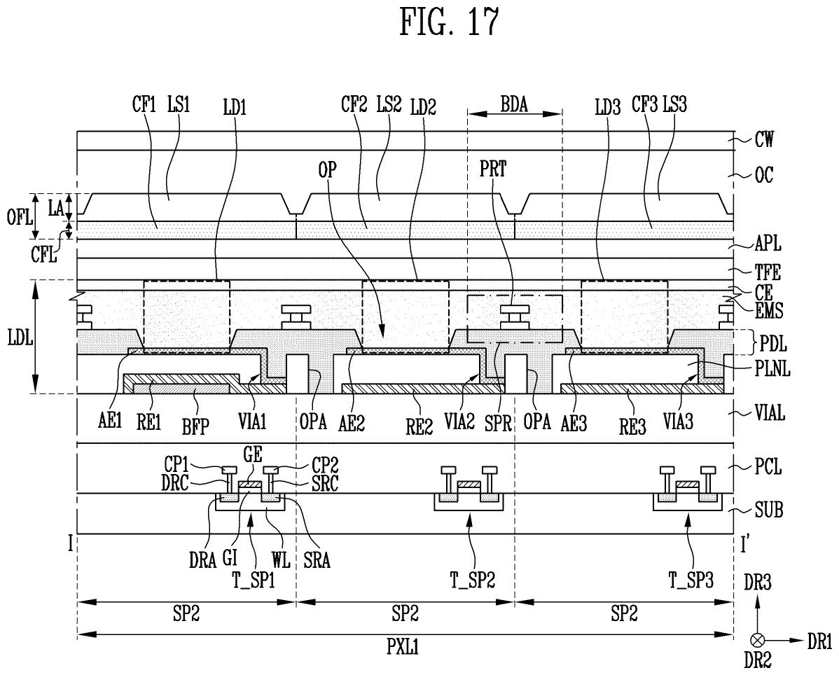

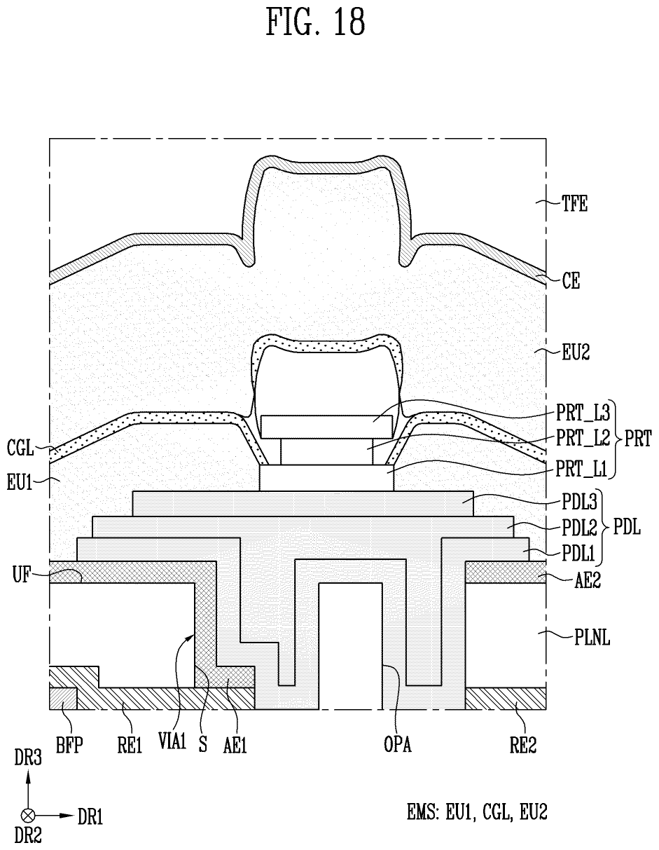

FIG. 17 is a schematic cross-sectional view illustrating still one or more other embodiments of the pixel taken along the line I˜I′ of FIG. 6A, and FIG. 18 is an enlarged schematic cross-sectional view of a portion of a display device of FIG. 17.

In FIG. 18, the planarization layer PLNL, the anode electrodes AE1 and AE2, the pixel-defining layer PDL, the light-emitting structure EMS, the cathode electrode CE, and the encapsulation layer TFE at a partial area including the protrusion pattern PRT (for example, the boundary area between the first sub-pixel (refer to “SP1” of FIG. 17) and the second sub-pixel (refer to “SP2” of FIG. 17)) are shown.

In FIGS. 17 and 18, a repeated description overlapping the one or more embodiments corresponding to FIG. 7 is omitted for convenience of description.

Referring to FIGS. 17 and 18, the planarization layer PLNL may include the first via VIA1 exposing one area of the first reflective electrode RE1, the second via VIA2 exposing one area of the second reflective electrode RE2, and the third via VIA3 exposing one area of the third reflective electrode RE3.

A sidewall S of the first via VIA1 may be located adjacent to the buffer pattern BFP compared to one end of the first reflective electrode RE1 in the first direction DR1. In other words, the side wall S of the first via VIA1 may be positioned inside in a direction opposite to the first direction DR1 compared to the first reflective electrode RE1 to expose one end of the first reflective electrode RE1.

The first anode electrode AE1 may be electrically connected to the first reflective electrode RE1 exposed to the outside through the first via VIA1. The first anode electrode AE1 may be located on the sidewall S of the first via VIA1, and may be located on the first reflective electrode RE1. The first anode electrode AE1 may be physically and/or electrically connected to the first reflective electrode RE1 near one end (or one side surface) thereof. In this case, the first via VIA1 corresponding to a connection point for connecting the first anode electrode AE1 and the first reflective electrode RE1 may be located on a side of the first sub-pixel SP1 (or the boundary area between the first sub-pixel SP1 and the second sub-pixel SP2), and thus the area occupied by the first via VIA1 may be reduced, thereby securing an effect space in the first sub-pixel SP1.

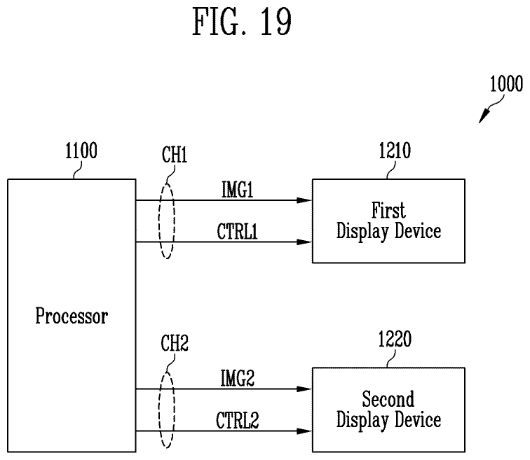

FIG. 19 is a schematic block diagram illustrating one or more embodiments of a display system 1000.

Referring to FIG. 19, the display system 1000 may include a processor 1100 and one or more display devices 1210 and 1220.

The processor 1100 may perform various tasks and calculations. In embodiments, the processor 1100 may include an application processor, a graphic processor, a microprocessor, a central processing component (CPU), and the like. The processor 1100 may be connected to other components of the display system 1000 through a bus system, and may control the other components.

In FIG. 19, the display system 1000 includes the first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may have the same configuration as the display device 100 described with reference to FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may have the same configuration as the display device 100 described with reference to FIG. 1.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra-mobile personal computer (UMPC). In addition, the display system 1000 may include at least one of a head-mounted display (HMD) device, a virtual reality (VR) device, a mixed reality (MR) device, or an augmented reality (AR) device.

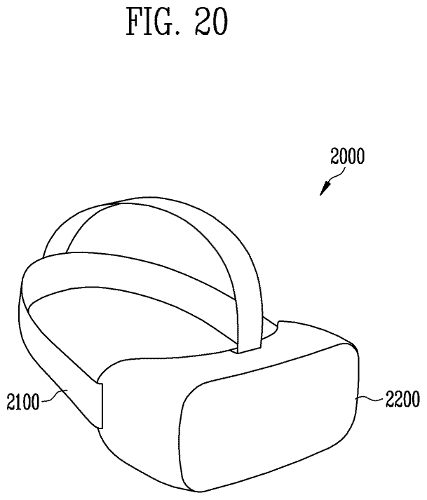

FIG. 20 is a schematic perspective view illustrating an application example of the display system of FIG. 19.

Referring to FIG. 20, the display system 1000 of FIG. 19 may be applied to a head-mounted display device 2000. The head-mounted display device 2000 may be a wearable electronic device that may be worn on a user's head.

The head-mounted display device 2000 may include a head mount band 2100 and a display device-receiving case 2200. The head mount band 2100 may be connected to the display device-receiving case 2200. The head mount band 2100 may include a horizontal band and/or a vertical band for fixing the head-mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device-receiving case 2200 may receive the first and second display devices 1210 and 1220 of FIG. 19. The display device-receiving case 2200 may further receive the processor 1100 of FIG. 19.

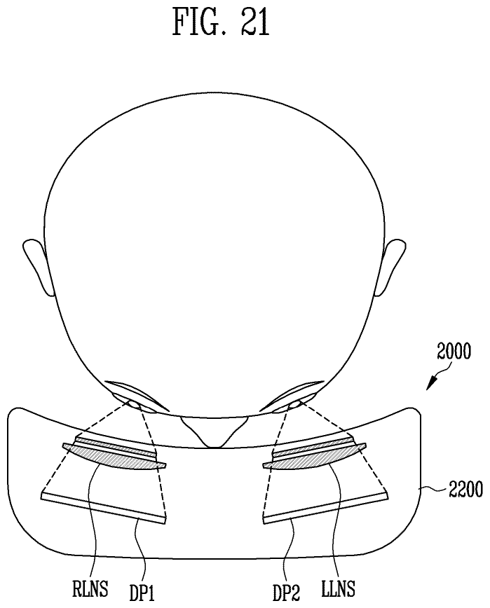

FIG. 21 is a schematic diagram illustrating a form in which a user wears the head-mounted display device of FIG. 20.

Referring to FIG. 21, in a head-mounted display device 2000, a first display panel DP1 of the first display device 1210 (refer to FIG. 19) and a second display panel DP2 of the second display device 1220 (refer to 19) are located. The head-mounted display device 2000 may further include one or more lenses LLNS and RLNS.

Within the display device-receiving case 2200, the right eye lens RLNS may be located between the first display panel DP1 and a user's right eye. Within the display device-receiving case 2200, the left eye lens LLNS may be located between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

Although embodiments and application examples are described herein, other embodiments and modified examples may be derived from the above description. Therefore, the technical scope of the disclosure is not limited to these embodiments, but may extend to the claims set forth below, various modifications, and equivalents.

What is claimed is:

1. A display device comprising:
a first sub-pixel, a second sub-pixel, and a third sub-pixel, the first sub-pixel, the second sub-pixel, and the third sub-pixel comprising:
a reflective electrode above a base layer;
a planarization layer above the reflective electrode, having a flat upper surface, defining a via exposing a portion of the reflective electrode, and comprising a first side surface and a second side surface facing each other with the via therebetween;
an anode electrode above the planarization layer, above an area of the reflective electrode exposed by the via, and directly connected to the reflective electrode;
a light-emitting structure above the anode electrode; and
a cathode electrode above the light-emitting structure,
wherein the first sub-pixel further comprises a buffer pattern between the base layer and the reflective electrode, and
wherein a separation distance between the anode electrode and the reflective electrode in the first sub-pixel is less than a separation distance between the anode electrode and the reflective electrode in the second sub-pixel and in the third sub-pixel.

2. The display device according to claim 1, wherein the reflective electrode is directly on the base layer in the second sub-pixel and the third sub-pixel.

3. The display device according to claim 1, wherein the buffer pattern comprises an insulating material.

4. The display device according to claim 1, wherein, in the first sub-pixel, the anode electrode is on the first side surface and the second side surface of the planarization layer, and is on the flat upper surface connected to the first side surface and the second side surface.

5. The display device according to claim 1, wherein, in the first sub-pixel, a sidewall of the via is closer to the buffer pattern than one end of the reflective electrode.

6. The display device according to claim 1, wherein one end of the reflective electrode is exposed through the via.

7. The display device according to claim 1, further comprising:
a pixel-defining layer above the anode electrode and the planarization layer; and
a protrusion pattern above the pixel-defining layer.

8. The display device according to claim 7, wherein the pixel-defining layer comprises a first inorganic insulating layer, a second inorganic insulating layer, and a third inorganic insulating layer sequentially stacked.

9. The display device according to claim 8, wherein the first inorganic insulating layer is above the anode electrode in the via.

10. The display device according to claim 7, wherein the protrusion pattern comprises:
a first protrusion pattern above the pixel-defining layer, and having a first width;
a second protrusion pattern above the first protrusion pattern, and having a second width that is less than the first width; and
a third protrusion pattern above the second protrusion pattern, and having a third width that is greater than the second width.

11. The display device according to claim 7, further comprising one or more trenches formed by recessing at least a portion of the pixel-defining layer in a boundary area between the first sub-pixel and the second sub-pixel and in a boundary area between the second sub-pixel and the third sub-pixel.

12. The display device according to claim 1, wherein the light-emitting structure comprises:
a first light-emitting layer commonly in the first sub-pixel, the second sub-pixel, and the third sub-pixel, and configured to emit light of a first color; and
a second light-emitting layer above the first light-emitting layer, and configured to emit light of a second color.

13. The display device according to claim 12, wherein the first light-emitting layer of the first sub-pixel and the second light-emitting layer of the second sub-pixel are separated.

14. The display device according to claim 12, wherein the light-emitting structure further comprises a third light-emitting layer above the second light-emitting layer, and configured to emit light of a third color.

15. A wearable electronic device comprising:
a display panel comprising a first sub-pixel, a second sub-pixel, and a third sub-pixel, the first sub-pixel, the second sub-pixel, and the third sub-pixel comprising:
a reflective electrode above a base layer;
a planarization layer above the reflective electrode, having a flat upper surface, defining a via exposing a portion of the reflective electrode, and comprising a first side surface and a second side surface facing each other with the via therebetween;
an anode electrode above the planarization layer, above an area of the reflective electrode exposed by the via, directly connected to the reflective electrode, and on the first side surface, the second side surface, and the flat upper surface connected to the first side surface and the second side surface, respectively;
a light-emitting structure above the anode electrode; and
a cathode electrode above the light-emitting structure; and
a lens on the display panel,
wherein the first sub-pixel further comprises a buffer pattern between the base layer and the reflective electrode.

16. The wearable electronic device according to claim 15, wherein the reflective electrode is directly above the base layer in the second sub-pixel and the third sub-pixel.

17. The wearable electronic device according to claim 15, wherein a separation distance between the anode electrode and the reflective electrode in the first sub-pixel is less than a separation distance between the anode electrode and the reflective electrode in the second sub-pixel and in the third sub-pixel.

18. A method of manufacturing a display device, the method comprising:
forming a buffer pattern above a base layer of a first sub-pixel;
forming a first reflective electrode above the buffer pattern;
forming a second reflective electrode directly on the base layer of a second sub-pixel;
forming a third reflective electrode directly on the base layer of a third sub-pixel;
forming a planarization layer covering the first reflective electrode, the second reflective electrode, and the third reflective electrode, and having a flat upper surface, by applying an insulating material layer on the first reflective electrode, the second reflective electrode, and the third reflective electrode, by arranging a mask on the insulating material layer, and by performing a photolithography process; and
forming a light-emitting element above the planarization layer.

19. The method according to claim 18, wherein a thickness of the insulating material layer on the first reflective electrode, a thickness of the insulating material layer on the second reflective electrode, and a thickness of the insulating material layer on the third reflective electrode are substantially equal,
wherein the insulating material layer on the first reflective electrode protrudes upwardly further than the insulating material layer on the second reflective electrode and the insulating material layer on the third reflective electrode, and
wherein one area of the insulating material layer on the first reflective electrode is etched through a dry etching process of the photolithography process.

20. The method according to claim 19, further comprising forming a pixel-defining layer above the light-emitting element,
wherein the planarization layer defines a via exposing an area of the first reflective electrode, an area of the second reflective electrode, and an area of the third reflective electrode, and comprises a first side surface and a second side surface facing each other with the via therebetween, and
wherein the pixel-defining layer is in the via.
